(19) United States
(12) Patent Application Publication
(10) Pub. No.: US 2024/0206341 A1
(43) Pub. Date: Jun. 20, 2024

(54) LAMINATED PIEZOELECTRIC ELEMENT AND ELECTROACOUSTIC TRANSDUCER

(71) Applicant: FUJIFILM Corporation, Tokyo (JP)

(72) Inventor: Shun ISHIGE, Minamiashigara-shi (JP)

(73) Assignee: FUJIFILM Corporation, Tokyo (JP)

(21) Appl. No.: 18/595,522

(22) Filed: Mar. 5, 2024

Related U.S. Application Data
(63) Continuation of application No. PCT/JP2022/033553, filed on Sep. 7, 2022.

(30) Foreign Application Priority Data
Sep. 24, 2021 (JP) 2021-155452

(51) Int. Cl. H10N 30/50; H04R 17/00; H10N 30/045; H10N 30/073; H10N 30/20; H10N 30/87

(52) U.S. Cl. CPC H10N 30/508; H10N 30/045; H10N 30/073; H10N 30/202; H10N 30/871; H04R 17/005

(57) ABSTRACT

An object of the present invention is to provide a laminated piezoelectric element obtained by folding and laminating a piezoelectric film, in which, in a case where a pressure is applied, it is possible to prevent an electrode layer from breaking at a folded-back portion, and to provide an electroacoustic transducer using the laminated piezoelectric element. The object is achieved by including a bonding layer for bonding adjacent layers to each other in the lamination of the piezoelectric film, in which, in a case where a thickness of the bonding layer at a center portion in a folding-back direction of the piezoelectric film is denoted as d1 and a spacing between piezoelectric films at a folded-back portion of the piezoelectric film in a lamination direction is denoted as d2, a relationship of “d2<d1” is satisfied.

### CROSS-REFERENCE TO RELATED APPLICATIONS

This application is a Continuation of PCT International Application No. PCT/JP2022/033553 filed on Sep. 7, 2022, which claims priority under 35 U.S.C. § 119(a) to Japanese Patent Application No. 2021-155452 filed on Sep. 24, 2021. The above applications are hereby expressly incorporated by reference, in their entirety, into the present application.

### BACKGROUND OF THE INVENTION

### 1. Field of the Invention

The present invention relates to a laminated piezoelectric element obtained by laminating a plurality of piezoelectric materials, and an electroacoustic transducer using the laminated piezoelectric element.

### 2. Description of the Related Art

A so-called exciter, which is brought into contact and attached to various articles and vibrates the articles to generate a sound, has been used for various applications.

For example, in an office, by attaching the exciter to a conference table, a whiteboard, a screen, or the like during presentation, telephone conference, or the like, voice can be output instead of using a speaker. In a vehicle such as an automobile, by attaching the exciter to a console, an A pillar, a roof, or the like, a guide sound, a warning sound, music, or the like can be sounded. In addition, in an automobile which does not produce an engine sound, such as a hybrid vehicle and an electric vehicle, by attaching the exciter to a bumper or the like, a vehicle approach warning sound can be produced from the bumper or the like.

As a variable element which generates vibration in such an exciter, a combination of a coil and a magnet, a vibration motor such as an eccentric motor and a linear resonance motor, and the like have been known.

It is difficult to reduce a thickness of these variable elements. In particular, the vibration motor has disadvantages that a mass body needs to be increased in order to increase a vibration force, frequency modulation for controlling a degree of vibration is difficult, and a response speed is slow.

On the other hand, in recent years, the speaker is also required to have flexibility, for example, in response to the demand corresponding to a display having flexibility. However, it is difficult for a configuration consisting of the exciter and the vibration plate to correspond to the speaker having flexibility.

It is also considered that the speaker having flexibility is obtained by bonding an exciter having flexibility to a vibration plate having flexibility.

For example, WO2020/095812A discloses a laminated piezoelectric element in which a plurality of layers of piezoelectric films having a piezoelectric layer sandwiched between two thin film electrodes are laminated. The piezoelectric film in the laminated piezoelectric element is polarized in a thickness direction, a polarization direction of adjacent piezoelectric film is reversed.

In the laminated piezoelectric element, the piezoelectric film stretches and contracts in a plane direction by energizing the piezoelectric film. Therefore, by bonding the laminated piezoelectric element to the vibration plate as the exciter, a piezoelectric speaker can be realized in which stretch and contraction movement of the laminated piezoelectric films vibrates the vibration plate in a direction orthogonal to a bent plate surface of the vibration plate, and the vibration plate outputs the voice.

### SUMMARY OF THE INVENTION

In the laminated piezoelectric element as in WO2020/095812A, as one method of laminating the piezoelectric films, a method in which a plurality of layers of the piezoelectric films are laminated by folding the piezoelectric film in a bellows shape as disclosed in WO2020/095812A is considered.

In a case where a plurality of layers of cut sheet-like piezoelectric films are laminated, it is necessary to connect an electrode layer and an external device such as a power supply for each piezoelectric film. On the other hand, in a case where the piezoelectric film is folded and a plurality of layers are laminated, since the number of piezoelectric film is 1, the connection between the electrode layer and the external device such as a power supply may be performed at one place.

By the way, in a case where the laminated piezoelectric element is used as the exciter, it is necessary to bond the laminated piezoelectric element to the vibration plate as described above.

The laminated piezoelectric element is bonded to the vibration plate by, for example, pressing the laminated piezoelectric element against the vibration plate through a bonding agent such as a pressure sensitive adhesive.

Here, in the laminated piezoelectric element in which the piezoelectric film is folded and laminated, the piezoelectric film is folded with a small curvature in the folded-back portion of the piezoelectric film. Therefore, in the laminated piezoelectric element in which the piezoelectric film is folded and laminated, strength of the piezoelectric film in the folded-back portion is low.

In a case where such a laminated piezoelectric element is pressed against a vibration plate to be bonded to the vibration plate, there is a problem that the piezoelectric film is subjected to a force and the electrode layer or the like of the piezoelectric film is broken in the folded-back portion.

An object of the present invention is to solve such problems of the related art, and to provide a laminated piezoelectric element obtained by folding and laminating a piezoelectric film, in which, in a case where a pressure is applied, it is possible to prevent an electrode layer or the like from breaking at a folded-back portion of the piezoelectric film, and to provide an electroacoustic transducer using the laminated piezoelectric element.

In order to achieve such objects, the present invention has the following configurations.

[1] A laminated piezoelectric element obtained by folding a piezoelectric film having flexibility to laminate the piezoelectric film into a plurality of layers, the laminated piezoelectric element comprising:
a bonding layer for bonding adjacent layers to each other in the lamination of the piezoelectric film,
in which, in a case where a thickness of the bonding layer at a center portion in a folding-back direction of the piezoelectric film is denoted as d1 and a spacing between piezoelectric films at a folded-back portion of the piezoelectric film in a lamination direction of the piezoelectric film is denoted as d2, a relationship of “d2<d1” is satisfied.

[2] The laminated piezoelectric element according to [1],
in which a position of an outer end portion of the folded-back portion of the piezoelectric film matches in the folding-back direction of the piezoelectric film.

[3] The laminated piezoelectric element according to [1] or [2],
in which the piezoelectric film is polarized in a thickness direction.

[4] The laminated piezoelectric element according to any one of [1] to [3],
in which the piezoelectric film includes a piezoelectric layer, electrode layers provided on both surfaces of the piezoelectric layer, and protective layers provided to cover the electrode layers.

[5] The laminated piezoelectric element according to [4],
in which the piezoelectric layer is a polymer-based piezoelectric composite material having piezoelectric particles in a polymer material.

[6] The laminated piezoelectric element according to [5],
in which the polymer material has a cyanoethyl group.

[7] The laminated piezoelectric element according to [6],
in which the polymer material is cyanoethylated polyvinyl alcohol.

[8] The laminated piezoelectric element according to any one of [1] to [7],
in which the piezoelectric film has a rectangular shape in a case of being viewed in the lamination direction of the piezoelectric film.

[9] The laminated piezoelectric element according to any one of [1] to [8],
in which the piezoelectric film has a protruding portion where the piezoelectric film protrudes from a longest side which is a longest side in a case of being viewed in the lamination direction of the piezoelectric film, and
a length of the protruding portion in a longitudinal direction of the longest side is 10% or more of an entire length of the longest side.

[10] An electroacoustic transducer comprising:
the laminated piezoelectric element according to any one of [1] to [9]; and
a vibration plate to which the laminated piezoelectric element is fixed.

[11] The electroacoustic transducer according to [10],
in which the vibration plate has flexibility.

According to the present invention, in a laminated piezoelectric element obtained by folding and laminating a piezoelectric film, in a case where a pressure is applied, it is possible to prevent an electrode layer or the like from breaking at a folded-back portion.

### BRIEF DESCRIPTION OF THE DRAWINGS

FIG. 1 is a view conceptually showing an example of a laminated piezoelectric element according to an embodiment of the present invention.

FIG. 2 is a conceptual view for describing the example of the laminated piezoelectric element according to the embodiment of the present invention.

FIG. 3 is a conceptual view for describing another example of laminated piezoelectric element according to the embodiment of the present invention.

FIG. 4 is a view conceptually showing an example of a piezoelectric film used in the laminated piezoelectric element according to the embodiment of the present invention.

FIG. 5 is a conceptual view for describing an example of the production method of the piezoelectric film.

FIG. 6 is a conceptual view for describing the example of the production method of the piezoelectric film.

FIG. 7 is a conceptual view for describing the example of the production method of the piezoelectric film.

FIG. 8 is a conceptual view for describing the laminated piezoelectric element according to the embodiment of the present invention.

FIG. 9 is a conceptual view for describing the laminated piezoelectric element according to the embodiment of the present invention.

FIG. 10 is a conceptual view for describing the laminated piezoelectric element according to the embodiment of the present invention.

FIG. 11 is a conceptual view for describing an example of a manufacturing method of the laminated piezoelectric element.

FIG. 12 is a conceptual view for describing an example of a manufacturing method of the laminated piezoelectric element.

FIG. 13 is a conceptual view for describing an example of a manufacturing method of the laminated piezoelectric element according to the embodiment of the present invention.

FIG. 14 is a conceptual view for describing another example of a manufacturing method of the laminated piezoelectric element according to the embodiment of the present invention.

FIG. 15 is a view conceptually showing another example of the laminated piezoelectric element according to the embodiment of the present invention.

FIG. 16 is a view conceptually showing an example of a piezoelectric speaker according to an embodiment of the present invention.

### DESCRIPTION OF THE PREFERRED EMBODIMENTS

Hereinafter, the laminated piezoelectric element and electroacoustic transducer according to the embodiments of the present invention will be described in detail based on suitable embodiments shown in the accompanying drawings.

Although configuration requirements to be described below are described based on representative embodiments of the present invention, the present invention is not limited to the embodiments.

In addition, the drawings shown below are conceptual views for describing the laminated piezoelectric element and electroacoustic transducer according to the embodiments of the present invention. Therefore, the size, thickness, shape, positional relationship, and the like of each member and each site are different from the actual ones.

Any numerical range expressed using “to” in the present invention refers to a range including the numerical values before and after the “to” as a lower limit value and an upper limit value, respectively.

Further, in the present invention, the terms “first” and “second” attached to an electrode layer, a protective layer, or the like are attached for convenience to distinguish two members which are basically the same as each other and describe the laminated piezoelectric element and electroacoustic transducer according to the embodiments of the present invention. Therefore, the terms “first” and “second” in these members have no technical meaning and are irrelevant to the actual usage state and the positional relationship therebetween.

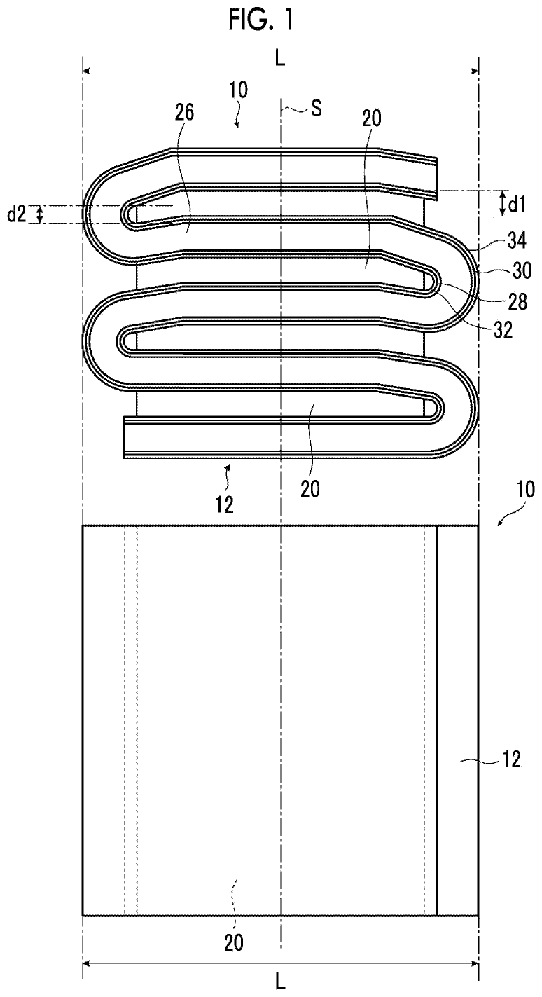

FIG. 1 conceptually illustrates an example of the laminated piezoelectric element according to the embodiment of the present invention. In FIG. 1, the upper part shows a front view of a laminated piezoelectric element 10, and the lower part shows a plan view thereof.

The front view is a view showing the laminated piezoelectric element according to the embodiment of the present invention as viewed in a plane direction of the piezoelectric film, which will be described later. In addition, the plan view is a view showing the laminated piezoelectric element according to the embodiment of the present invention as viewed in a lamination direction of the piezoelectric film, which will be described later. In other words, the plan view is a view of the laminated piezoelectric element as viewed in a direction orthogonal to a main surface of a piezoelectric film 12. The main surface is a maximum surface of a sheet-like material (a film, a plate-like material, or a layer), and is usually on both surfaces of the sheet-like material in a thickness direction.

In the following description, a case where the laminated piezoelectric element according to the embodiment of the present invention is viewed from the same direction as in the plan view is also referred to as “plan view” for convenience. In addition, a shape of the laminated piezoelectric element according to the embodiment of the present invention as viewed in a plane, that is, a shape of the laminated piezoelectric element in the plan view is also referred to as “planar shape” for convenience.

Further, in the following description, a lamination direction of the piezoelectric film 12 is also referred to as “lamination direction”.

A laminated piezoelectric element 10 shown in FIG. 1 is formed by laminating the piezoelectric film 12 in a plurality of layers by folding the piezoelectric film 12 having flexibility a plurality of times in a bellows shape. The piezoelectric film 12 includes a first electrode layer 28 on one surface of a piezoelectric layer 26, a second electrode layer 30 on the other surface, a first protective layer 32 on a surface of the first electrode layer 28, and a second protective layer 34 on a surface of the second electrode layer 30.

In addition, in the laminated piezoelectric element 10, adjacent piezoelectric film 12 folded and laminated is bonded by a bonding layer 20.

The laminated piezoelectric element 10 in the illustrated example has five layers of the piezoelectric film 12 laminated by folding the rectangular (oblong) piezoelectric film 12 four times at equal intervals.

Therefore, a planar shape of the laminated piezoelectric element 10 is rectangular as shown in the lower part of FIG. 1.

In the laminated piezoelectric element 10 according to the embodiment of the present invention, in a case where the rectangular piezoelectric film 12 is folded, a folding-back line formed by folding the piezoelectric film 12 may coincide with a longitudinal direction in the planar shape of the laminated piezoelectric element 10, or may coincide with a lateral direction.

In the following description, the folding-back line formed at an outer end part by folding the piezoelectric film 12, that is, a line of an outer apex of an end part of the folded-back portion is also referred to as “ridge line” for convenience.

As an example, the laminated piezoelectric element 10 having a rectangular planar shape of 20×5 cm will be described.

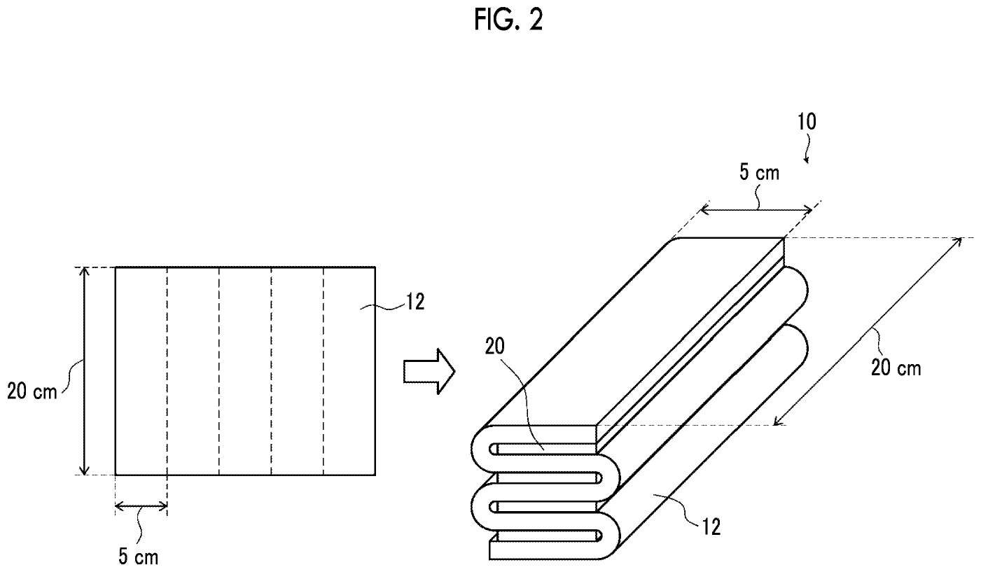

As conceptually shown in FIG. 2, the laminated piezoelectric element 10 according to the embodiment of the present invention may be a laminated piezoelectric element 10 with a length of 20 cm, having a configuration in which a rectangular piezoelectric film 12 of 20×25 cm is folded by 5 cm in a direction of a side of 25 cm, so that the ridge line is in the longitudinal direction.

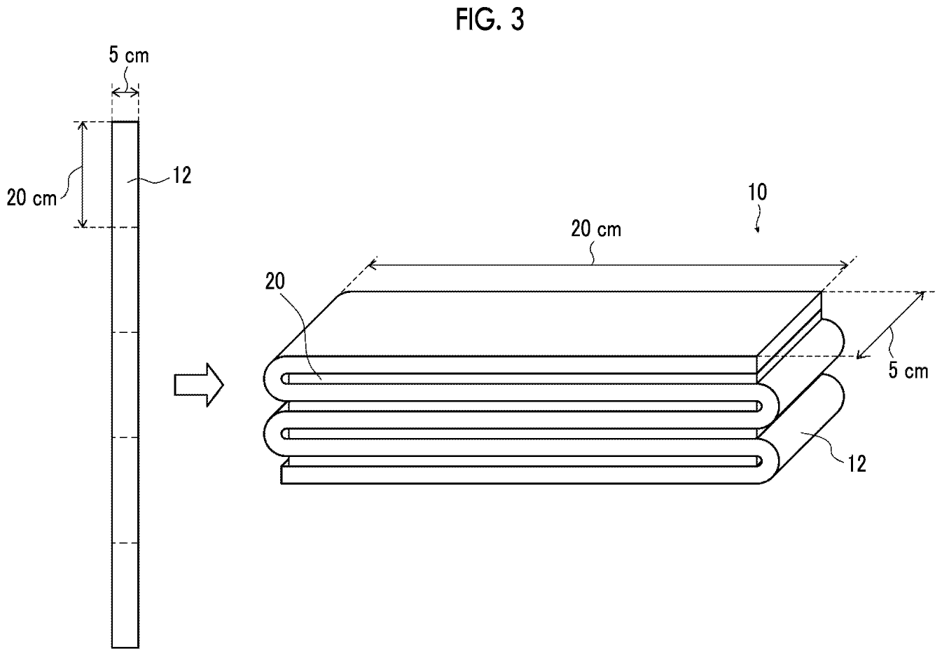

Alternatively, as conceptually shown in FIG. 3, the laminated piezoelectric element 10 according to the embodiment of the present invention may be a laminated piezoelectric element 10 with a length of 5 cm, having a configuration in which a rectangular piezoelectric film 12 of 100×5 cm is folded by 20 cm in a direction of a side of 100 cm, so that the ridge line is in the lateral direction.

In addition, in FIGS. 2 and 3, the thickness of the bonding layer 20 is shown to be uniform.

As a preferred aspect, the laminated piezoelectric elements 10 shown in FIGS. 1 to 3 are produced by folding the rectangular piezoelectric film 12, and thus have a rectangular planar shape. However, in the laminated piezoelectric element according to the embodiment of the present invention, the shape of the piezoelectric film 12 is not limited to the rectangle, and various shapes can be used.

Examples thereof include a circular shape, a rectangular shape with rounded corners (elongated shape), an elliptical shape, and a polygonal shape such as a hexagonal shape.

As described above, the laminated piezoelectric element 10 is formed by folding and laminating the piezoelectric film 12 a plurality of times. The laminated piezoelectric element 10 in the illustrated example has five layers of the piezoelectric film 12 laminated by folding the piezoelectric film 12 four times. In addition, the adjacent piezoelectric films 12 laminated are bonded to each other by the bonding layer 20.

In the laminated piezoelectric element 10 according to the embodiment of the present invention, since a plurality of piezoelectric films 12 are laminated and the adjacent piezoelectric films 12 are bonded, as compared with a case where one sheet of the piezoelectric film is used, stretching and contracting force as the laminated piezoelectric element can be increased. As a result, for example, a vibration plate described later can be bent with a large force, and a voice with a high sound pressure can be output.

In addition, in the laminated piezoelectric element 10 according to the embodiment of the present invention, in a case where a thickness of the bonding layer 20 at a center portion S (position indicated by one-dot chain line) in a folding-back direction is denoted as d1 and a spacing between the piezoelectric films at the folded-back portion in the lamination direction is denoted as d2, “d2<d1” is satisfied.

Since the laminated piezoelectric element 10 according to the embodiment of the present invention has such a configuration, in a case where the laminated piezoelectric element is pressurized in the lamination direction, such as in a case where the laminated piezoelectric element is bonded to the vibration plate described later, in the folded-back portion of the piezoelectric film 12, the electrode layer is prevented from being broken. This will be described in detail later.

In the laminated piezoelectric element 10 according to the embodiment of the present invention, the number of lamination of the piezoelectric film 12 in the laminated piezoelectric element 10 is not limited to the five layers in the illustrated example. That is, the laminated piezoelectric element 10 according to the embodiment of the present invention may be a piezoelectric element in which the piezoelectric film 12 is laminated in four or less layers by folding the piezoelectric film 12 three or less times, or may be a piezoelectric element in which the piezoelectric film 12 is laminated in six or more layers by folding the piezoelectric film 12 five or more times.

In the laminated piezoelectric element according to the embodiment of the present invention, the number of lamination of the piezoelectric film 12 is not limited, but is preferably 2 to 10 layers and more preferably 3 to 7 layers.

In the folded and laminated piezoelectric film 12 of the laminated piezoelectric element 10, piezoelectric films 12 adjacent to each other in the lamination direction are bonded to each other through the bonding layer 20.

By bonding the piezoelectric films 12 adjacent in the lamination direction with the bonding layer 20, stretch and contraction of each piezoelectric film 12 can be directly transmitted, and it is possible to drive without waste as a laminate of the laminated piezoelectric film 12.

In the present invention, as the bonding layer 20, various known bonding agents (bonding materials) can be used as long as the adjacent piezoelectric films 12 can be bonded.

Therefore, the bonding layer 20 may be a layer consisting of an adhesive (adhesive material), a layer consisting of a pressure sensitive adhesive (pressure sensitive adhesive material), or a layer consisting of a material having characteristics of both an adhesive and a pressure sensitive adhesive. The adhesive is a bonding agent which has fluidity in a case of bonding layers and is to be a solid state. In addition, the pressure sensitive adhesive is a bonding agent which is a gel-like (rubber-like) flexible solid in a case of bonding layers and whose gel-like state does not change thereafter.

In addition, the bonding layer 20 may be formed by applying a bonding agent having fluidity such as a liquid, or may also be formed by using a sheet-like bonding agent.

Here, the laminated piezoelectric element 10 is used as an exciter as an example. That is, the laminated piezoelectric element 10 itself stretches and contracts in a case where the plurality of layers of the laminated piezoelectric film 12 stretch and contract, and generates a sound by bending and vibrating a vibration plate 62 described later, for example. Therefore, in the laminated piezoelectric element 10, it is preferable that the stretch and contraction of each of the laminated piezoelectric film 12 is directly transmitted. In a case where a substance having viscosity, which relieves vibration, is present between the piezoelectric films 12, efficiency of transmitting the stretching and contracting energy of the piezoelectric film 12 is lowered, and driving efficiency of the laminated piezoelectric element 10 is also decreased.

In consideration of this point, it is preferable that the bonding layer 20 is an adhesive layer consisting of an adhesive from which a solid and hard bonding layer 20 is obtained, rather than a pressure sensitive adhesive layer consisting of a pressure sensitive adhesive. As a more preferred bonding layer 20, specifically, a bonding layer consisting of a thermoplastic type adhesive such as a polyester-based adhesive and a styrene-butadiene rubber (SBR)-based adhesive is suitably exemplified.

The adhesion, unlike pressure sensitive adhesion, is useful in a case where a high adhesion temperature is required. In addition, the thermoplastic type adhesive has “comparatively low temperature, short time, and strong adhesion”, which is suitable.

In the laminated piezoelectric element 10, a thickness of the bonding layer 20 is not limited, and a thickness capable of exhibiting sufficient bonding strength may be appropriately set depending on the forming material of the bonding layer 20.

Here, in the laminated piezoelectric element 10, as the bonding layer 20 is thinner, the effect of transmitting the stretching and contracting energy (vibration energy) of the piezoelectric layer 26 is higher, and the energy efficiency is higher. In addition, in a case where the bonding layer 20 is thick and has high rigidity, there is also a possibility that the stretch and contraction of the piezoelectric film 12 may be constrained.

In consideration of this point, it is preferable that the bonding layer 20 is thinner than the piezoelectric layer 26. That is, in the laminated piezoelectric element 10, the bonding layer 20 is preferably hard and thin. Specifically, the thickness of the bonding layer 20 is preferably 0.1 to 50 μm, more preferably 0.1 to 30 μm, and still more preferably 0.1 to 10 μm in terms of thickness after bonding.

In the laminated piezoelectric element according to the embodiment of the present invention, various known piezoelectric films 12 can be used as the piezoelectric film 12 as long as these films have flexibility which can be bent and stretched.

In the present invention, the expression of “having flexibility” is synonymous with having flexibility in the general interpretation, and indicates being capable of bending and being flexible, specifically, being capable of bending and stretching without causing breakage and damage.

In the laminated piezoelectric element 10 according to the embodiment of the present invention, as a preferred aspect, the piezoelectric film 12 includes electrode layers provided on both surfaces of the piezoelectric layer 26, and protective layers provided to cover the electrode layers.

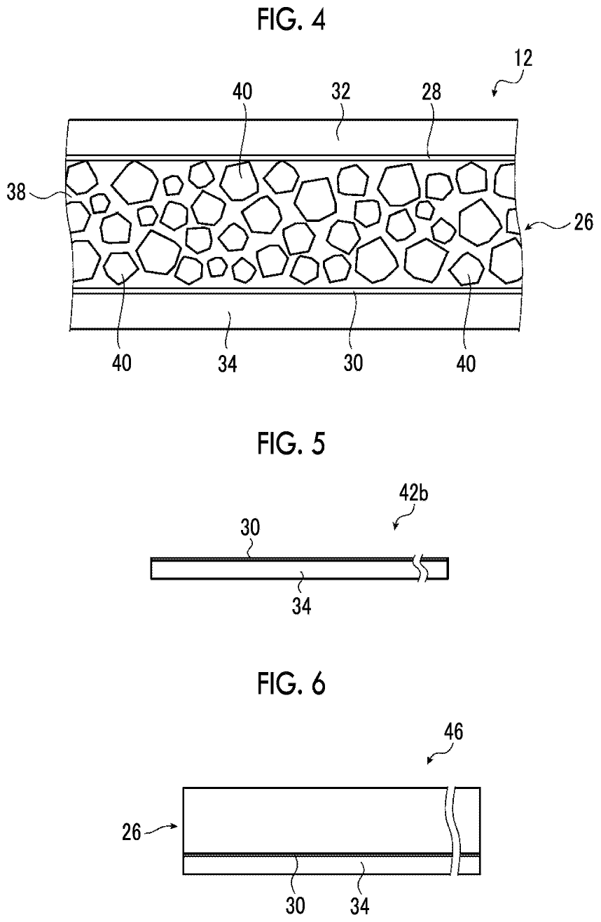

FIG. 4 is a cross-sectional view conceptually showing an example of the piezoelectric film 12. In FIG. 4 and the like, hatching will be omitted in order to clarify the configuration by simplifying the drawing.

In the following description, a “cross section” indicates a cross section of the piezoelectric film in a thickness direction, unless otherwise specified. The thickness direction of the piezoelectric film is the lamination direction of the piezoelectric film.

As shown in FIG. 4, the piezoelectric film 12 in the illustrated example includes a piezoelectric layer 26, a first electrode layer 28 laminated on one surface of the piezoelectric layer 26, a first protective layer 32 laminated on the first electrode layer 28, a second electrode layer 30 laminated on the other surface of the piezoelectric layer 26, and a second protective layer 34 laminated the second electrode layer 30.

As described above, in the laminated piezoelectric element 10 according to the embodiment of the present invention, the piezoelectric film 12 is laminated by folding one sheet of the piezoelectric film 12.

Therefore, although the piezoelectric film 12 is laminated in a plurality of layers, an electrode for driving the laminated piezoelectric element 10, that is, the piezoelectric film 12 can be led out at one place for each electrode layer described later. As a result, the configuration of the laminated piezoelectric element 10 and the lead out of the electrode can be simplified, and the productivity is also excellent. In addition, since one sheet of the piezoelectric film 12 is folded and laminated, electrode layers facing each other by the adjacent piezoelectric films by the lamination have the same polarity, even in a case where the electrode layers come into contact with each other, there is no short.

In the piezoelectric film 12, various known piezoelectric layers can be used as the piezoelectric layer 26.

In the piezoelectric film 12, as conceptually shown in FIG. 4, the piezoelectric layer 26 is preferably a polymer-based piezoelectric composite material including the piezoelectric particles 40 in the polymer matrix 38 including the polymer material.

Here, it is preferable that the polymer-based piezoelectric composite material (piezoelectric layer 26) satisfies the following requirements. In the present invention, normal temperature is in a range of 0° ° C. to 50° C.

### (i) Flexibility

For example, in a case of being gripped in a state of being loosely bent with a sense of document such as a newspaper and a magazine as a portable device, the polymer-based piezoelectric composite material is continuously subjected to large bending deformation from the outside at a comparatively slow vibration of less than or equal to a few Hz. At this time, in a case where the polymer-based piezoelectric composite material is rigid, large bending stress is generated to that extent, and a crack is generated at an interface between the polymer matrix and the piezoelectric particles, which may lead to breakage. Accordingly, the polymer-based piezoelectric composite material is required to have suitable flexibility. In addition, in a case where strain energy is diffused into the outside as heat, the stress can be relaxed. Therefore, the polymer-based piezoelectric composite material is required to have a suitably large loss tangent.

### (ii) Acoustic Quality

In a speaker, the piezoelectric particles vibrate at a frequency of an audio band of 20 Hz to 20 kHz, and vibration energy causes the entire vibration plate (polymer-based piezoelectric composite material) to vibrate integrally so that sound is reproduced. Therefore, in order to increase transmission efficiency of the vibration energy, the polymer-based piezoelectric composite material is required to have appropriate rigidity. In addition, in a case where frequency characteristics of the speaker are smooth, an amount of a change in acoustic quality decreases in a case where the lowest resonance frequency f₀ is changed in association with a change in curvature of the speaker. Therefore, the polymer-based piezoelectric composite material is required to have a suitably large loss tangent.

It has been known that the lowest resonance frequency f₀ of the vibration plate for a speaker is represented by the following expression. Here, s represents the stiffness of the vibration system, and m represents the mass.

$$Lowest resonance frequency : {f}_{0} = \frac{1}{2 π} \sqrt{\frac{s}{m}}$$

Here, as a degree of bending of the piezoelectric film, that is, a curvature radius of a bending portion increases, a mechanical stiffness s decreases, and thus the lowest resonance frequency f₀ decreases. That is, acoustic quality (volume and frequency characteristics) of the speaker changes depending on the curvature radius of the piezoelectric film.

Accordingly, the polymer-based piezoelectric composite material is required to exhibit a behavior of being rigid with respect to a vibration of 20 Hz to 20 kHz and being flexible with respect to a vibration of less than or equal to a few Hz. In addition, the loss tangent of the polymer-based piezoelectric composite material is required to be suitably large with respect to the vibration of all frequencies of 20 kHz or less.

In general, a polymer solid has a viscoelasticity relaxing mechanism, and a molecular movement with a large scale is observed as a decrease (relaxation) in a storage clastic modulus (Young's modulus) or a maximal value (absorption) in a loss elastic modulus along with an increase in temperature or a decrease in frequency. Among these, the relaxation due to a microbrown movement of a molecular chain in an amorphous region is referred to as main dispersion, and an extremely large relaxing phenomenon is observed. A temperature at which this main dispersion occurs is a glass transition point (Tg), and the viscoelasticity relaxing mechanism is most remarkably observed.

In the polymer-based piezoelectric composite material (piezoelectric layer 26), the polymer-based piezoelectric composite material exhibiting a behavior of being rigid with respect to the vibration of 20 Hz to 20 KHz and being flexible with respect to the slow vibration of less than or equal to a few Hz is achieved by using, as a matrix, a polymer material having a glass transition point at normal temperature, that is, a polymer material having viscoelasticity at normal temperature. In particular, from the viewpoint that such a behavior is suitably exhibited, it is preferable that the polymer material in which the glass transition point Tg at a frequency of 1 Hz is at normal temperature is used for the matrix of the polymer-based piezoelectric composite material.

In the polymer material serving as the polymer matrix 38, it is preferable that the maximal value of a loss tangent Tan δ at a frequency of 1 Hz according to a dynamic viscoelasticity test at normal temperature is 0.5 or more.

In this manner, in a case where the polymer-based piezoelectric composite material is slowly bent due to an external force, stress concentration on the interface between the polymer matrix and the piezoelectric particles at the maximum bending moment portion is relaxed, and thus high flexibility can be expected.

In addition, in the polymer material serving as the polymer matrix 38, it is preferable that a storage elastic modulus (E′) at a frequency of 1 Hz according to the dynamic viscoelasticity measurement is 100 MPa or more at 0° C. and 10 MPa or less at 50° C.

In this manner, a bending moment generated in a case where the polymer-based piezoelectric composite material is slowly bent due to the external force can be reduced, and at the same time, the polymer-based piezoelectric composite material can exhibit a behavior of being rigid with respect to an acoustic vibration of 20 Hz to 20 KHz.

In addition, it is more suitable that a relative permittivity of the polymer material serving as the polymer matrix 38 is 10 or more at 25° C. Accordingly, in a case where a voltage is applied to the polymer-based piezoelectric composite material, a higher electric field is applied to the piezoelectric particles in the polymer matrix, and thus a large deformation amount can be expected.

However, in consideration of ensuring favorable moisture resistance and the like, it is suitable that the relative permittivity of the polymer material is 10 or less at 25° C.

Suitable examples of the polymer material satisfying such conditions include cyanoethylated polyvinyl alcohol (cyanoethylated PVA), polyvinyl acetate, poly(vinylidene chloride-co-acrylonitrile), a polystyrene-vinyl polyisoprene block copolymer, polyvinyl methyl ketone, and polybutyl methacrylate.

In addition, as these polymer materials, a commercially available product such as Hybrar 5127 (manufactured by Kuraray Co., Ltd.) can also be suitably used.

Among these, as the polymer material constituting the polymer matrix 38, it is preferable to use a polymer material having a cyanoethyl group and particularly preferable to use cyanoethylated PVA. That is, in the piezoelectric film 12, as the polymer matrix 38 of the piezoelectric layer 26, it is preferable to use a polymer material containing a cyanoethyl group and particularly preferable to use cyanoethylated PVA.

In the following description, the above-described polymer materials typified by cyanoethylated PVA will also be collectively referred to as “polymer material having viscoelasticity at normal temperature”.

These polymer materials having viscoelasticity at normal temperature may be used alone or in combination (mixture) of two or more kinds thereof.

In the piezoelectric film 12, a plurality of polymer materials may be used in combination as necessary for the polymer matrix 38 of the piezoelectric layer 26.

That is, for the purpose of adjustment of dielectric characteristics, mechanical characteristics, or the like, other dielectric polymer materials may be added to the polymer matrix 38 constituting the polymer-based piezoelectric composite material in addition to the polymer material having viscoelasticity at normal temperature, as necessary.

Examples of the dielectric polymer material which can be added thereto include fluorine-based polymers such as polyvinylidene fluoride, a vinylidene fluoride-tetrafluoroethylene copolymer, a vinylidene fluoride-trifluoroethylene copolymer, a polyvinylidene fluoride-trifluoroethylene copolymer, and a polyvinylidene fluoride-tetrafluoroethylene copolymer; polymers having a cyano group or a cyanoethyl group, such as a vinylidene cyanide-vinyl acetate copolymer, cyanoethyl cellulose, cyanoethyl hydroxysaccharose, cyanoethyl hydroxycellulose, cyanoethyl hydroxypullulan, cyanoethyl methacrylate, cyanocthyl acrylate, cyanoethyl hydroxyethyl cellulose, cyanoethyl amylose, cyanocthyl hydroxypropyl cellulose, cyanoethyl dihydroxypropyl cellulose, cyanocthyl hydroxypropyl amylose, cyanoethyl polyacrylamide, cyanoethyl polyacrylate, cyanoethyl pullulan, cyanoethyl polyhydroxymethylene, cyanoethyl glycidol pullulan, cyanoethyl saccharose, and cyanoethyl sorbitol; and synthetic rubber such as nitrile rubber and chloroprene rubber.

Among these, a polymer material having a cyanoethyl group is suitably used.

In addition, in the polymer matrix 38 of the piezoelectric layer 26, the number of these dielectric polymer materials is not limited to one, and a plurality of kinds of dielectric polymer materials may be added.

In addition, for the purpose of adjusting the glass transition point Tg of the polymer matrix 38, a thermoplastic resin such as a vinyl chloride resin, polyethylene, polystyrene, a methacrylic resin, polybutene, and isobutylene, a thermosetting resin such as a phenol resin, a urea resin, a melamine resin, an alkyd resin, and mica, or the like may be added, in addition to the dielectric polymer material.

Furthermore, for the purpose of improving pressure sensitive adhesiveness, a viscosity imparting agent such as rosin ester, rosin, terpene, terpene phenol, and a petroleum resin may be added.

In the polymer matrix 38 of the piezoelectric layer 26, the addition amount in a case of adding polymer materials other than the polymer material having viscoelasticity at normal temperature is not particularly limited, but is preferably set to 30% by mass or less in terms of the proportion of the polymer materials in the polymer matrix 38.

In this manner, characteristics of the polymer material to be added can be exhibited without impairing the viscoelasticity relaxing mechanism in the polymer matrix 38, so that preferred results such as an increase in permittivity, improvement of heat resistance, and improvement of adhesiveness between the piezoelectric particles 40 and the electrode layer can be obtained.

The polymer-based piezoelectric composite material serving as the piezoelectric layer 26 contains the piezoelectric particles 40 in the polymer matrix. The piezoelectric particles 40 are dispersed in the polymer matrix, preferably dispersed uniformly (substantially uniform).

It is preferable that the piezoelectric particles 40 consist of ceramic particles having a perovskite type or wurtzite type crystal structure.

Examples of the ceramic particles constituting the piezoelectric particles 40 include lead zirconate titanate (PZT), lead lanthanum zirconate titanate (PLZT), barium titanate (BaTiO₃), zinc oxide (ZnO), and a solid solution (BFBT) of barium titanate and bismuth ferrite (BiFe₃).

A particle diameter of the piezoelectric particles 40 may be appropriately selected according to the size and the applications of the piezoelectric film 12. The particle diameter of the piezoelectric particles 40 is preferably 1 to 10 μm.

By setting the particle diameter of the piezoelectric particles 40 to be within the above-described range, preferred results in terms of achieving both excellent piezoelectric characteristics and flexibility can be obtained.

In the piezoelectric film 12, the ratio between the amount of the polymer matrix 38 and the amount of the piezoelectric particles 40 in the piezoelectric layer 26 may be appropriately set according to the size and the thickness of the piezoelectric film 12 in the plane direction, the applications of the piezoelectric film 12, the characteristics required for the piezoelectric film 12, and the like.

A volume fraction of the piezoelectric particles 40 in the piezoelectric layer 26 is preferably 30% to 80% and more preferably 50% to 80%.

By setting the ratio between the amount of the polymer matrix 38 and the amount of the piezoelectric particles 40 to be within the above-described range, preferred results in terms of achieving both of excellent piezoelectric characteristics and flexibility can be obtained.

In the piezoelectric film 12, a thickness of the piezoelectric layer 26 is not limited and may be appropriately set according to the size of the piezoelectric film 12, the applications of the piezoelectric film 12, the characteristics required for the piezoelectric film 12, and the like.

The thickness of the piezoelectric layer 26 is preferably 8 to 300 μm, more preferably 8 to 200 μm, still more preferably 10 to 150 μm, and particularly preferably 15 to 100 μm.

By setting the thickness of the piezoelectric layer 26 to be within the above-described ranges, preferred results in terms of achieving both ensuring of the rigidity and moderate elasticity can be obtained.

It is preferable that the piezoelectric layer 26 is subjected to a polarization treatment (poling) in the thickness direction. The polarization treatment will be described later in detail.

In the piezoelectric film 12, the piezoelectric layer 26 is not limited to the polymer-based piezoelectric composite material containing the piezoelectric particles 40 in the polymer matrix 38 consisting of a polymer material having viscoelasticity at normal temperature, such as cyanoethylated PVA, as described above.

That is, in the piezoelectric film 12, various known piezoelectric layers can be used as the piezoelectric layer.

As an example, a polymer-based piezoelectric composite material containing the same piezoelectric particles 40 in a matrix containing a dielectric polymer material such as polyvinylidene fluoride, a vinylidene fluoride-tetrafluoroethylene copolymer, and a vinylidene fluoride-trifluoroethylene copolymer described above, a piezoelectric layer consisting of polyvinylidene fluoride, a piezoelectric layer consisting of a fluororesin other than polyvinylidene fluoride, a piezoelectric layer obtained by laminating a film consisting of poly-L lactic acid and a film consisting of poly-D lactic acid, and the like are also available.

However, as described above, from the viewpoint that the polymer-based piezoelectric composite material can behave rigid for vibrations at 20 Hz to 20 kHz and behave softly for slow vibrations at less than or equal to a few Hz, has excellent acoustic characteristics, and has excellent flexibility, a polymer-based piezoelectric composite material containing piezoelectric particles 40 in a polymer matrix 38 consisting of a polymer material having viscoelasticity at normal temperature, such as cyanoethylated PVA described above, is suitably used.

The piezoelectric film 12 shown in FIG. 4 has a configuration in which the second electrode layer 30 is provided on one surface of such a piezoelectric layer 26, the second protective layer 34 is provided on a surface of the second electrode layer 30, the first electrode layer 28 is provided on the other surface of the piezoelectric layer 26, and the first protective layer 32 is provided on a surface of the first electrode layer 28. In the piezoelectric film 12, the first electrode layer 28 and the second electrode layer 30 form an electrode pair.

In other words, the laminated film constituting the piezoelectric film 12 has a configuration in which both surfaces of the piezoelectric layer 26 are sandwiched between the electrode pair, that is, the first electrode layer 28 and the second electrode layer 30, and further sandwiched between the first protective layer 32 and the second protective layer 34.

In this manner, a region sandwiched between the first electrode layer 28 and the second electrode layer 30 is driven according to the applied voltage.

The piezoelectric film 12 may include, in addition to those layers, for example, a bonding layer for bonding the electrode layer and the piezoelectric layer 26 to each other, and a bonding layer for bonding the electrode layer and the protective layer to each other.

The bonding agent may be an adhesive or a pressure sensitive adhesive. In addition, the same material as the polymer material obtained by removing the piezoelectric particles 40 from the piezoelectric layer 26, that is, the polymer matrix 38 can also be suitably used as the bonding agent. The bonding layer may be provided on both the first electrode layer 28 side and the second electrode layer 30 side, or may be provided only on one of the first electrode layer 28 side or the second electrode layer 30 side.

The first protective layer 32 and the second protective layer 34 in the piezoelectric film 12 have a function of coating the first electrode layer 28 and the second electrode layer 30 and imparting moderate rigidity and mechanical strength to the piezoelectric layer 26. That is, the piezoelectric layer 26 containing the polymer matrix 38 and the piezoelectric particles 40 in the piezoelectric film 12 exhibits extremely excellent flexibility under bending deformation at a slow vibration, but may have insufficient rigidity or mechanical strength depending on the applications. As a compensation for this, the piezoelectric film 12 is provided with the first protective layer 32 and the second protective layer 34.

The first protective layer 32 and the second protective layer 34 have the same configuration despite of different disposition positions. Accordingly, in the following description, in a case where it is not necessary to distinguish the first protective layer 32 from the second protective layer 34, both members are collectively referred to as a protective layer.

In the present invention, the first protective layer 32 and the second protective layer 34 are used as a preferred aspect, and are not essential configuration requirements. Therefore, the piezoelectric film 12 may include only the first protective layer 32, may include only the second protective layer 34, or may include no protective layer.

However, in consideration of mechanical strength of the piezoelectric film 12, protective property of the electrode layer, and the like, it is preferable that the piezoelectric film includes at least one protective layer, and it is more preferable to include two protective layers to cover both electrode layers, as shown in the illustrated example.

The protective layer is not limited, and various sheet-like materials can be used as the protective layer, and suitable examples thereof include various resin films. Among these, from the viewpoint of excellent mechanical characteristics and heat resistance, a resin film consisting of polyethylene terephthalate (PET), polypropylene (PP), polystyrene (PS), polycarbonate (PC), polyphenylene sulfite (PPS), polymethylmethacrylate (PMMA), polyetherimide (PEI), polyimide (PI), polyamide (PA), polyethylene naphthalate (PEN), triacetyl cellulose (TAC), a cyclic olefin-based resin, and the like is suitably used.

A thickness of the protective layer is not limited. In addition, the thicknesses of the first protective layer 32 and the second protective layer 34 are basically the same as each other, but may be different from each other.

Here, in a case where the rigidity of the protective layer is extremely high, not only is the stretch and contraction of the piezoelectric layer 26 constrained, but also the flexibility is impaired. Therefore, it is advantageous that the thickness of the protective layer decreases except for a case where the mechanical strength or excellent handleability as a sheet-like material is required.

In a case where the thickness of the first protective layer 32 and the thickness of the second protective layer 34 are each twice or less the thickness of the piezoelectric layer 26, preferred results from the viewpoints of achieving both ensuring of the rigidity and moderate elasticity, and the like can be obtained.

For example, in a case where the thickness of the piezoelectric layer 26 is 50 μm and the first protective layer 32 and the second protective layer 34 consist of PET, the thicknesses of the first protective layer 32 and the second protective layer 34 are each preferably 100 μm or less, more preferably 50 μm or less, and still more preferably 25 μm or less.

In the piezoelectric film 12, the first electrode layer 28 is formed between the piezoelectric layer 26 and the first protective layer 32, and the second electrode layer 30 is formed between the piezoelectric layer 26 and the second protective layer 34. The first electrode layer 28 and the second electrode layer 30 are for applying a voltage to the piezoelectric layer 26. The piezoelectric film 12 stretches and contracts by applying a voltage from the electrode layer to the piezoelectric layer 26.

The first electrode layer 28 and the second electrode layer 30 are basically the same, except that the positions are different. Accordingly, in the following description, in a case where it is not necessary to distinguish the first electrode layer 28 and the second electrode layer 30, both members are collectively referred to as an electrode layer.

In the piezoelectric film, a forming material of the electrode layer is not limited, and various conductors can be used as the forming material. Specific examples thereof include conductive polymers such as carbon, palladium, iron, tin, aluminum, nickel, platinum, gold, silver, copper, chromium, molybdenum, alloys thereof, indium tin oxide, and polyethylene dioxythiophene-polystyrene sulfonic acid (PEDOT/PPS).

Among these, copper, aluminum, gold, silver, platinum, or indium tin oxide is suitably exemplified. Among these, from the viewpoint of the conductivity, the cost, and the flexibility, copper is more preferable.

In addition, a method of forming the electrode layer is not limited, and various known methods, for example, a vapor-phase deposition method (a vacuum film forming method) such as vacuum vapor deposition or sputtering, a film forming method using plating, a method of bonding a foil formed of the materials described above, and a coating method can be used.

Among these, particularly from the viewpoint of ensuring the flexibility of the piezoelectric film 12, a thin film made of copper or aluminum formed by vacuum vapor deposition is suitably used as the electrode layer. Among these, a thin film made of copper, which is formed by vacuum vapor deposition, is particularly suitably used.

Thicknesses of the first electrode layer 28 and the second electrode layer 30 are not limited. In addition, the thicknesses of the first electrode layer 28 and the second electrode layer 30 are basically the same as each other, but may be different from each other.

Here, similarly to the protective layer described above, in a case where the rigidity of the electrode layer is extremely high, not only is the stretch and contraction of the piezoelectric layer 26 constrained, but also the flexibility is impaired. Therefore, it is advantageous that the thickness of the electrode layer is reduced in a case where an electric resistance is not excessively high.

In the piezoelectric film 12, it is suitable that a product of the thickness of the electrode layer and the Young's modulus thereof is less than a product of the thickness of the protective layer and the Young's modulus thereof because the flexibility is not considerably impaired.

For example, a case where the first protective layer 32 and the second protective layer 34 are made of PET and the first electrode layer 28 and the second electrode layer 30 are made of copper is exemplified. In this case, a Young's modulus of PET is approximately 6.2 GPa, and a Young's modulus of copper is approximately 130 GPa. Therefore, in a case where the thickness of the protective layer is 25 μm, a thickness of the electrode layer is preferably 1.2 μm or less, more preferably 0.3 μm or less, and still more preferably 0.1 μm or less.

The piezoelectric film 12 has a configuration in which the piezoelectric layer 26 is sandwiched between the first electrode layer 28 and the second electrode layer 30, and this laminate is further sandwiched between the first protective layer 32 and the second protective layer 34.

It is preferable that, in such a piezoelectric film 12, the maximal value at which the loss tangent (Tan δ) at a frequency of 1 Hz according to dynamic viscoelasticity measurement is 0.1 or more is present at normal temperature.

In this manner, even in a case where the piezoelectric film 12 is subjected to large bending deformation at a relatively slow vibration of less than or equal to a few Hz from the outside, since the strain energy can be effectively diffused to the outside as heat, occurrence of cracks at the interface between the polymer matrix and the piezoelectric particles can be prevented.

In the piezoelectric film 12, it is preferable that the storage elastic modulus (E′) at a frequency of 1 Hz according to the dynamic viscoelasticity measurement is 10 to 30 GPa at 0° C. and 1 to 10 GPa at 50° C.

In such a manner, the piezoelectric film 12 may have large frequency dispersion in the storage elastic modulus (E′) at normal temperature. That is, the piezoelectric film 12 can exhibit a behavior of being rigid with respect to the vibration of 20 Hz to 20 kHz and being flexible with respect to the vibration of less than or equal to a few Hz.

In the piezoelectric film 12, it is preferable that a product of the thickness and the storage elastic modulus (E′) at a frequency of 1 Hz according to the dynamic viscoelasticity measurement is 1.0×10⁶ to 2.0×10⁶ N/m at 0° C. and 1.0×10⁵ to 1.0×10⁶ N/m at 50° C.

In this manner, the piezoelectric film 12 may have moderate rigidity and mechanical strength within a range not impairing the flexibility and the acoustic characteristics.

Furthermore, in the piezoelectric film 12, it is preferable that the loss tangent (Tan δ) at a frequency of 1 kHz at 25° C. is 0.05 or more in a master curve obtained from the dynamic viscoelasticity measurement.

Next, an example of a manufacturing method of the piezoelectric film 12 will be described with reference to FIGS. 5 to 7.

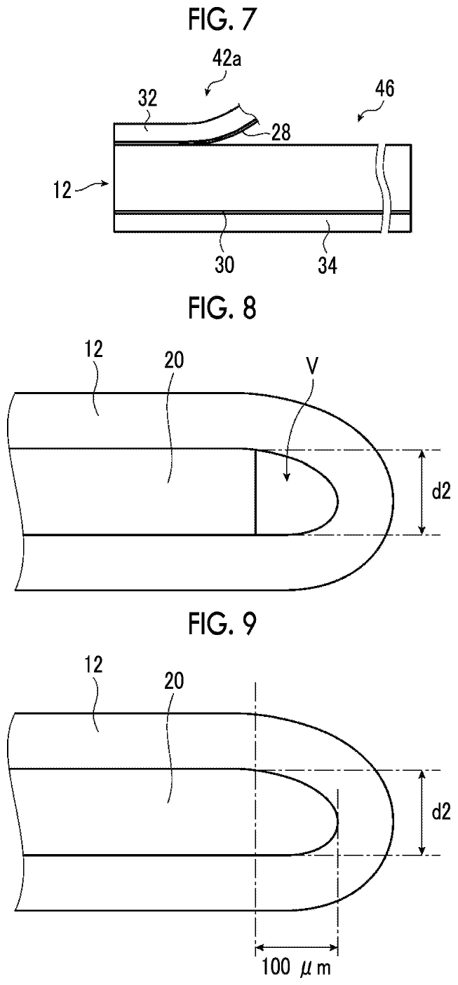

First, as conceptually shown in FIG. 5, a sheet-like material 42b in which the second electrode layer 30 has been formed on a surface of the second protective layer 34 is prepared. Furthermore, as conceptually shown in FIG. 7, a sheet-like material 42a in which the first electrode layer 28 has been formed on a surface of the first protective layer 32 is prepared.

The sheet-like material 42b may be produced by forming a copper thin film or the like as the second electrode layer 30 on the surface of the second protective layer 34 using vacuum vapor deposition, sputtering, plating, or the like. Similarly, the sheet-like material 42a may be produced by forming a copper thin film or the like as the first electrode layer 28 on the surface of the first protective layer 32 using vacuum vapor deposition, sputtering, plating, or the like.

Alternatively, a commercially available sheet-like material in which a copper thin film or the like is formed on a protective layer may be used as the sheet-like material 42b and/or the sheet-like material 42a.

The sheet-like material 42b and the sheet-like material 42a may be exactly the same or different from each other.

In a case where the protective layer is extremely thin and thus the handleability is degraded, the protective layer with a separator (temporary support) may be used as necessary. PET having a thickness of 25 to 100 μm, or the like can be used as the separator. The separator may be removed after thermal compression bonding of the electrode layer and the protective layer.

Next, as conceptually shown in FIG. 6, a laminate 46 is produced by forming the piezoelectric layer 26 on the second electrode layer 30 of the sheet-like material 42b, and laminating the sheet-like material 42b and the piezoelectric layer 26.

The piezoelectric layer 26 may be formed by a known method with the piezoelectric layer 26.

For example, in a case of the piezoelectric layer (polymer-based piezoelectric composite material layer) in which the piezoelectric particles 40 are dispersed in the polymer matrix 38 shown in FIG. 4, the piezoelectric layer is produced as follows by way of an example.

First, the coating material is prepared by dissolving the above-described polymer material such as cyanoethylated PVA in an organic solvent, adding the piezoelectric particles 40 such as PZT particles thereto, and stirring the solution. The organic solvent is not limited, and various organic solvents such as dimethylformamide (DMF), methyl ethyl ketone, and cyclohexanone can be used.

In a case where the sheet-like material 42b is prepared and the coating material is prepared, the coating material is cast (applied) onto the sheet-like material 42b, and the organic solvent is evaporated and dried. In this manner, as shown in FIG. 6, the laminate 46 in which the second electrode layer 30 is provided on the second protective layer 34 and the piezoelectric layer 26 is laminated on the second electrode layer 30 is produced.

A casting method of the coating material is not limited, and all known methods (coating devices) such as a bar coater, a slide coater, and a doctor knife can be used.

Alternatively, in a case where the polymer material is a material that can be heated and melted, the laminate 46 as shown in FIG. 6 may be produced by heating and melting the polymer material to produce a melt obtained by adding the piezoelectric particles 40 to the melted material, extruding the melt on the sheet-like material 42b shown in FIG. 5 in a sheet shape by carrying out extrusion molding or the like, and cooling the laminate.

As described above, in the piezoelectric layer 26, a polymer piezoelectric material such as PVDF may be added to the polymer matrix 38, in addition to the polymer material having viscoelasticity at normal temperature.

In a case where the polymer piezoelectric material is added to the polymer matrix 38, the polymer piezoelectric material to be added to the above-described coating material may be dissolved. Alternatively, the polymer piezoelectric material to be added may be added to the heated and melted polymer material having viscoelasticity at normal temperature so that the polymer piezoelectric material is heated and melted.

After forming the piezoelectric layer 26, a calender treatment may be performed as necessary. The calender treatment may be performed once or a plurality of times.

As is well known, the calender treatment is a treatment in which the surface to be treated is pressed while being heated by a heating press, a heating roller, a heating roller pair, or the like to flatten the surface.

In addition, the piezoelectric layer 26 of the laminate 46 including the second electrode layer 30 on the second protective layer 34 and including the piezoelectric layer 26 formed on the second electrode layer 30 is subjected to a polarization treatment (poling).

A method of performing the polarization treatment on the piezoelectric layer 26 is not limited, and a known method can be used. For example, electric field poling in which a DC electric field is directly applied to a target to be subjected to the polarization treatment is exemplified. In a case of performing the electric field poling, the electric field poling treatment may be performed using the first electrode layer 28 and the second electrode layer 30 by forming the first electrode layer 28 before the polarization treatment.

In addition, in a case where the piezoelectric film 12 is produced, it is preferable that the polarization treatment is performed in the thickness direction instead of the plane direction of the piezoelectric layer 26.

Next, as conceptually shown in FIG. 7, the sheet-like material 42a which has been prepared in advance is laminated on the piezoelectric layer 26 side of the laminate 46 such that the first electrode layer 28 faces the piezoelectric layer 26.

Furthermore, the laminate is subjected to thermal compression bonding using a heating press device, a heating roller, or the like such that the laminate is sandwiched between the first protective layer 32 and the second protective layer 34, thereby bonding the laminate 46 and the sheet-like material 42a.

In this manner, the piezoelectric film 12 consisting of the piezoelectric layer 26, the first electrode layer 28 and the second electrode layer 30 provided on both surfaces of the piezoelectric layer 26, and the first protective layer 32 and the second protective layer 34 formed on the surfaces of the electrode layers is produced.

The piezoelectric film 12 to be produced in the above-described manner is polarized in the thickness direction instead of the plane direction, and thus excellent piezoelectric characteristics are obtained even in a case where a stretching treatment is not performed after the polarization treatment. Therefore, the piezoelectric film 12 has no in-plane anisotropy as a piezoelectric characteristic, and stretches and contracts isotropically in all directions in the plane direction in a case where a driving voltage is applied.

As described above, the laminated piezoelectric element 10 is formed by laminating the piezoelectric film in a plurality of layers by folding the piezoelectric film 12, in which the adjacent laminated piezoelectric films 12 are bonded through the bonding layer 20.

Here, in the present invention, the thickness of the bonding layer 20 at the center of the folding-back direction of the piezoelectric film 12 is denoted as d1. In addition, the spacing between the piezoelectric films 12 at the folded-back portion in the lamination direction of the piezoelectric film 12 sandwiching the bonding layer 20 is denoted as d2. In the laminated piezoelectric element 10 according to the embodiment of the present invention, the d1 and the d2 satisfy “d2<d1”.

Specifically, in the laminated piezoelectric element 10 according to the embodiment of the present invention, with regard to the thickness d1 of the bonding layer 20 at the center of the folding-back direction of the piezoelectric film 12 and the spacing d2 between the piezoelectric films 12 at the folded-back portion of the piezoelectric film 12 sandwiching the bonding layer 20 in the lamination direction, an average of spacings d2 of the folded-back portion on one side in the folding-back direction (for example, the left side in FIG. 1) and an average of thicknesses d1 of the bonding layer 20 sandwiched between the piezoelectric films 12 folded at the folded-back portion satisfy “d2<d1”, and an average of spacings d2 of the folded-back portion on the other side in the folding-back direction (for example, the right side in FIG. 1) and an average of thicknesses d1 of the bonding layer 20 sandwiched between the piezoelectric films 12 folded at the folded-back portion satisfy “d2<d1”.

For example, in each of folded-back portions on the right side and on the left side of the laminated piezoelectric element 10 shown in FIG. 1, an average of a thickness d1 of a first bonding layer 20 from the top in the drawing and a thickness d1 of a third bonding layer 20 from the top in the drawing, and an average of a spacing d2 at a first folded-back portion (left side) from the top in the drawing and a spacing d2 at a third folded-back portion (left side) from the top in the drawing satisfy “d2<d1”; and an average of a thickness d1 of a second bonding layer 20 from the top in the drawing and a thickness d1 of a fourth bonding layer 20 from the top in the drawing, and an average of a spacing d2 at a second folded-back portion (right side) from the top in the drawing and a spacing d2 at a fourth folded-back portion (right side) from the top in the drawing satisfy “d2<d1”.

In the present invention, the thickness d1 of the bonding layer 20 at the center in the folding-back direction of the piezoelectric film 12 in the laminated piezoelectric element 10 is a thickness of the bonding layer 20 at the center portion S (one-dot chain line) of a length Lin the folding-back direction of the laminated piezoelectric element 10 as shown in FIG. 1.

In other words, the thickness d1 of the bonding layer 20 at the center in the folding-back direction of the piezoelectric film 12 is a thickness of the bonding layer 20 at the center portion S between outer folded end parts which are most spaced from each other in a case where the laminated piezoelectric element 10 is viewed in the lamination direction. That is, in a case where the planar shape of the laminated piezoelectric element 10 is rectangular as in the illustrated example, a thickness of the bonding layer 20 at the center of the side in the folding-back direction is the thickness d1.

On the other hand, in the present invention, the spacing d2 between the piezoelectric films in the lamination direction at the folded-back portion of the piezoelectric film 12 in the laminated piezoelectric element 10, that is, a bending region of the piezoelectric film by the folding is defined in each of the cases where the folded-back portion of the piezoelectric film 12 has or does not have a void in an inner end part.

A case where the inner end part of the folded-back portion of the piezoelectric film 12 has a void V is conceptually shown in FIG. 8. In the configuration, an end part of the bonding layer 20 is positioned on an inner side in the folding-back direction with respect to an inner end part of the folded-back portion of the piezoelectric film 12.

In this case, as shown in FIG. 8, a spacing between the piezoelectric films 12 at a position where the piezoelectric films 12 are most spaced in the lamination direction in the void V is defined as the spacing d2.

In the example shown in FIG. 8, the position of the end part of the bonding layer 20 is the position where the piezoelectric films are most spaced in the lamination direction in the void V. Therefore, in this case, the spacing between the piezoelectric films 12 in the lamination direction at the end part of the bonding layer 20, that is, the thickness of an edge surface of the bonding layer 20 is defined as the spacing d2 in the lamination direction of the piezoelectric film 12 at the folded-back portion.

FIG. 1 and the like show this state.

Meanwhile, a case where the inner end part of the folded-back portion of the piezoelectric film 12 does not have the void V is conceptually shown in FIG. 9. In this configuration, the bonding layer 20 is present up to the inner end part of the folded-back portion of the piezoelectric film 12.

In this case, as shown in FIG. 9, in a region within 100 μm from the inner end part of the folded-back portion of the piezoelectric film 12, a spacing in the lamination direction between the piezoelectric films 12 at a position where the piezoelectric films 12 are most spaced in the lamination direction is defined as the spacing d2.

In the example shown in FIG. 9, within 100 μm from the inner end part of the folded-back portion of the piezoelectric film 12, the piezoelectric films 12 are most spaced from the position of 100 μm in the lamination direction. Therefore, in this case, the spacing between the piezoelectric films 12 at a position of 100 μm from the inner end part of the folded-back portion of the piezoelectric film 12 is the spacing d2 between the piezoelectric films 12 at the folded-back portion.

In the following description, the thickness d1 of the bonding layer 20 at the center portion of the folding-back direction of the piezoelectric film 12 in the laminated piezoelectric element 10 will also be referred to as “bonding layer thickness d1” for convenience.

In addition, the spacing d2 of the piezoelectric film 12 in the lamination direction at the folded-back portion of the laminated piezoelectric element 10 is also referred to as “film spacing d2” for convenience.

In the laminated piezoelectric element 10 according to the embodiment of the present invention, since the bonding layer thickness d1 and the film spacing d2 satisfy “d2<d1”, in a case where the laminated piezoelectric element 10 is pressed in the lamination direction, for example, a case where the laminated piezoelectric element 10 is bonded to the vibration plate, it is possible to prevent the electrode layer from being broken in the folded-back portion of the piezoelectric film 12. As a result, for example, in a case where the laminated piezoelectric element 10 according to the embodiment of the present invention is used in a piezoelectric speaker as an exciter, it is possible to appropriately perform set operation and to appropriately perform voice output at a target sound pressure.

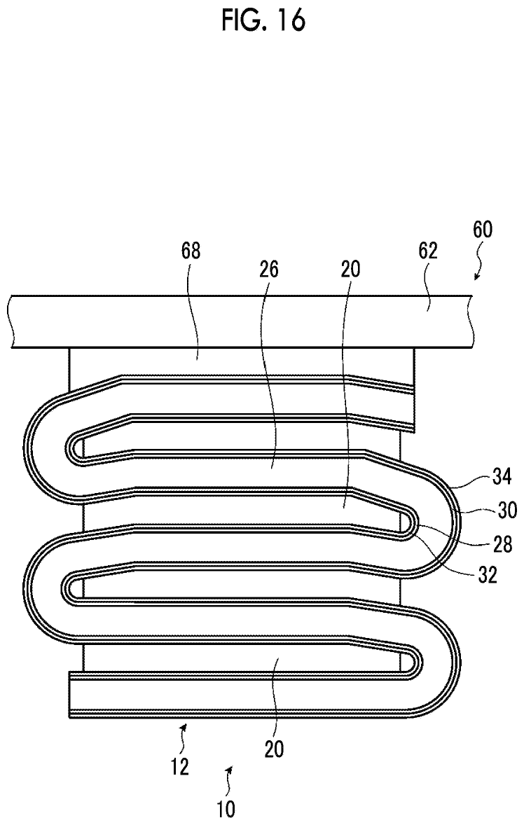

As described above, the laminated piezoelectric element in which the piezoelectric film 12 is folded and laminated is used as an exciter which vibrates a vibration plate to output a voice, as an example. In a case where the piezoelectric speaker is produced using the laminated piezoelectric element as the exciter, it is necessary to bond the laminated piezoelectric element 10 to the vibration plate 62 as conceptually shown in FIG. 16 described later.

The laminated piezoelectric element is bonded to the vibration plate by, for example, pressing the laminated piezoelectric element against the vibration plate through a bonding agent such as a pressure sensitive adhesive. In addition, the pressing is performed while heating the bonding agent, that is, the laminated piezoelectric element and/or the vibration plate as necessary.

Here, in the laminated piezoelectric element in which the piezoelectric film is folded and laminated, a force is applied to the piezoelectric film in the folded-back portion during this pressing.

In the folded-back portion of the piezoelectric film 12, the piezoelectric film is folded with a small curvature. As a result, the piezoelectric film 12 in the folded-back portion has a lower hardness than those in other portions. Therefore, in a case where a force is applied to the piezoelectric film 12 at the folded-back portion due to the pressing of the laminated piezoelectric element, there is a problem that the electrode of the piezoelectric film 12 is broken in the folded-back portion. In particular, this problem is likely to occur in an environment of low temperature and low humidity, such as in winter.

On the other hand, with regard to the laminated piezoelectric element 10 according to the embodiment of the present invention, in the laminated piezoelectric element in which the piezoelectric film 12 is laminated by folding the piezoelectric film 12, the bonding layer thickness d1, which is the thickness of the bonding layer 20 at the center portion of the piezoelectric film 12 in the folding-back direction, and the film spacing d2, which is the spacing between the piezoelectric films 12 in the folded-back portion, satisfy “d2<d1”.

The laminated piezoelectric element 10 according to the embodiment of the present invention is a laminated piezoelectric element in which the piezoelectric film 12 is laminated in a plurality of layers by folding one sheet of the piezoelectric film 12. Therefore, in the present invention, the thickness of the piezoelectric film 12 is uniform (substantially uniform) over the entire surface.

Therefore, the fact that the bonding layer thickness d1 at the center in the folding-back direction and the film spacing d2 at the folded-back portion satisfy “d2<d1” indicates that, in the laminated piezoelectric element 10 according to the embodiment of the present invention, the thickness of the center portion in the folding-back direction is larger than the thickness of the folded-back portion.

In the pressing for bonding the laminated piezoelectric element 10 to the vibration plate, the laminated piezoelectric element 10 is subjected to a high pressure at a thick portion of the laminated piezoelectric element 10. In the present invention, unless otherwise specified, the thickness is the thickness of the piezoelectric film 12 in the lamination direction.

Therefore, in the laminated piezoelectric element 10 according to the embodiment of the present invention in which the bonding layer thickness d1 and the film spacing d2 satisfy “d2<d1”, the center portion in the folding-back direction is subjected to a higher pressure than in the folded-back portion. That is, the center portion of the laminated piezoelectric element 10 in the folding-back direction receives a large part of the pressure applied by the pressing, and the pressure, that is, the force applied to the piezoelectric film 12 of the folded-back portion can be reduced.

As a result, in the laminated piezoelectric element 10 according to the embodiment of the present invention, it is possible to prevent the electrode layer of the piezoelectric film 12 from being broken in the folded-back portion during pressing against the vibration plate. In addition, since the piezoelectric film 12 is substantially planar except for the folded-back portion, the electrode layer is not broken even in a case where a high surface pressure is applied. Therefore, the laminated piezoelectric element 10 according to the embodiment of the present invention can appropriately perform a predetermined operation even after being pressed by being bonded to the vibration plate. Accordingly, for example, the piezoelectric speaker using the laminated piezoelectric element 10 according to the embodiment of the present invention as the exciter can appropriately perform voice output of the set sound pressure.

In the laminated piezoelectric element 10 according to the embodiment of the present invention, the bonding layer thickness d1 and the film spacing d2 may satisfy “d2<d1”, and a difference therebetween is not limited.

The difference between the bonding layer thickness d1 and the film spacing d2 is preferably 1 μm or more, more preferably 10 μm or more, and still more preferably 50 μm or more.

From the viewpoint that it is possible to more suitably prevent damage to the electrode layer of the piezoelectric film 12 in the folded-back portion, it is preferable that the difference between the bonding layer thickness d1 and the film spacing d2 is 1 μm or more.

In addition, from the viewpoint that the breakage of the electrode layer of the piezoelectric film 12 in the folded-back portion can be prevented, the difference between the bonding layer thickness d1 and the film spacing d2 is preferably large. However, the difference between the bonding layer thickness d1 and the film spacing d2 is preferably 100 μm or less.

In a case where the difference between the bonding layer thickness d1 and the film spacing d2 is too large, there is a possibility that inconvenience such as difficulty in bonding to the vibration plate or the like, instability of the stretch and contraction of the laminated piezoelectric element 10 in the plane direction, and an increase in the thickness of the laminated piezoelectric element 10 and a decrease in the flexibility may occur. On the other hand, by setting the difference between the bonding layer thickness d1 and the film spacing d2 within the above-described range, it is possible to suitably avoid the occurrence of these inconveniences.

Although the bonding layer thickness d1 and the film spacing d2 are shown for the uppermost bonding layer 20 in FIG. 1, in a laminated piezoelectric element in which the piezoelectric film 12 is laminated in three or more layers by folding one sheet of the piezoelectric film two or more times, a plurality of bonding layers 20 are present. For example, as shown in FIG. 1, in a case where the piezoelectric film 12 is laminated in five layers by folding the piezoelectric film 12 four times, there are four bonding layers 20.

In the present invention, the bonding layer thickness d1 and the film spacing d2 in the piezoelectric films 12 sandwiching the bonding layer 20 are measured in all the bonding layers 20. Based on this, as described above, the average of the bonding layer thicknesses d1 corresponding to the folded-back portions on the right side in the drawing and the average of the film spacings d2 are calculated, and the average of the bonding layer thicknesses d1 corresponding to the folded-back portions on the left side in the drawing and the average of the film spacings d2 are calculated. As described above, in the laminated piezoelectric element according to the embodiment of the present invention, the average of the bonding layer thicknesses d1 and the average of the film spacings d2 in both of the folded-back portions satisfy “d2<d1”.

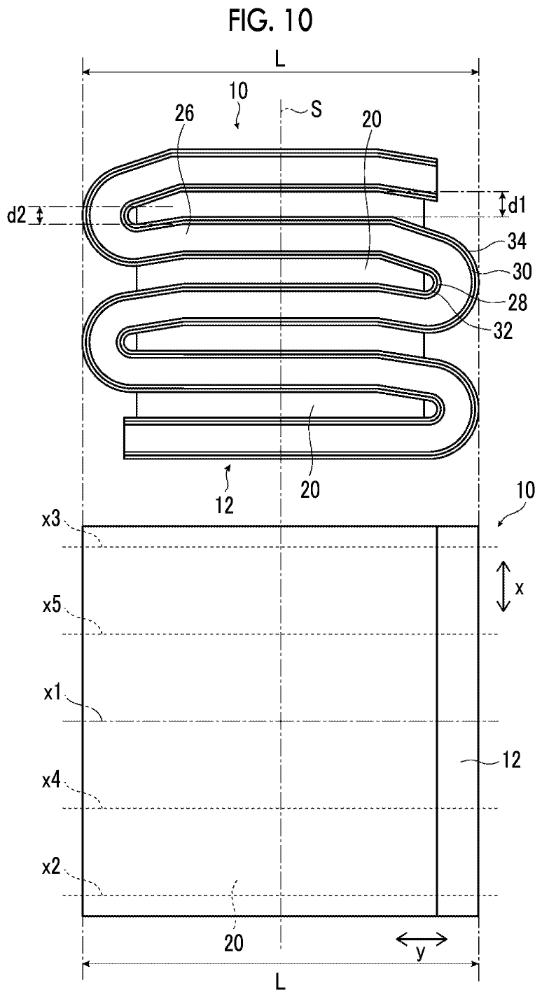

Hereinafter, with reference to FIG. 10, a method of measuring the bonding layer thickness d1 and the film spacing d2 in the laminated piezoelectric element 10 will be described.

In the following description, for convenience, a direction of the folding-back line at the folded end part due to folding of the piezoelectric film 12, that is, a direction of the ridge line of the piezoelectric film 12 at the folded-back portion is referred to as an x direction. In addition, a direction orthogonal to the x direction which is the direction of the ridge line, that is, the folding-back direction of the piezoelectric film 12 in the laminated piezoelectric element 10 is referred to as a y direction.

In the present invention, as conceptually shown in a plan view of the lower part of FIG. 10, the bonding layer thickness d1 and the film spacing d2 of the laminated piezoelectric element 10 are determined by measuring five lines of a center measurement line x1 which is a center line in the x direction, a measurement line x2 and a measurement line x3 in the y direction, which are positioned inside from the end part in the x direction by 5% of the length of the laminated piezoelectric element 10 in the x direction, that is, the length of the ridge line, and a measurement line x4 in the y direction, which is positioned in the middle between the center measurement line x1 and the measurement line x2, and a measurement line x5 in the y direction, which is positioned in the middle between the center measurement line x1 and the measurement line x3.

First, with regard to a bonding layer 20 to be measured, a thickness of the bonding layer, that is, the bonding layer thickness d1 in the center portion in the folding-back direction, that is, the center portion S is measured at all positions of the center measurement line x1 and the measurement lines x2 to x5 of the laminated piezoelectric element 10.

In addition, in the folded-back portion of the piezoelectric film 12 in which the bonding layer 20 is sandwiched, as shown in FIGS. 8 and 9, the spacing of the piezoelectric film 12 in the lamination direction at the folded-back portion, that is, the film spacing d2 is measured at all the positions of the center measurement line x1 and the measurement lines x2 to x5 of the laminated piezoelectric element 10.

Therefore, in this measurement method, the bonding layer thickness d1 and the film spacing d2 are measured at five positions in the ridge line direction, that is, the x direction.

The bonding layer thickness d1 and the film spacing d2 in each measurement line may be obtained by observing the center portion and the folded-back portion with a scanning electron microscope (SEM) in a cross section taken along each measurement line, and may be measured by a known method using an SEM image.

In this way, in a case where the bonding layer thickness d1 and the film spacing d2 are measured in all of the center measurement line x1 and the measurement lines x2 to x5, the average of the five bonding layer thicknesses d1 and the average of the five film spacings d2 are calculated. The calculated average is set as the bonding layer thickness d1 in the bonding layer 20 to be measured and the film spacing d2 in the folded-back portion of the piezoelectric films 12 sandwiching the bonding layer 20.

In the present invention, the measurement of the bonding layer thickness d1 and the film spacing d2 is performed on all the bonding layers 20 of the laminated piezoelectric element. That is, in the laminated piezoelectric element 10 shown in FIG. 1, the bonding layer thickness d1 and the film spacing d2 are measured for all the four bonding layers 20. Based on this, as described above, the average of the bonding layer thicknesses d1 corresponding to the folded-back portions on the right side in the drawing and the average of the film spacings d2 are calculated, and the average of the bonding layer thicknesses d1 corresponding to the folded-back portions on the left side in the drawing and the average of the film spacings d2 are calculated.

In the laminated piezoelectric element 10 of the illustrated example, the positions of the ridge lines of the folded end parts in the laminated piezoelectric films 12 match each other in the folding-back direction. However, in the laminated piezoelectric element 10 according to the embodiment of the present invention, the positions of the ridge lines of the folded end parts in the laminated piezoelectric films 12 may or may not coincide with each other in the folding-back direction.

In the laminated piezoelectric element 10 according to the embodiment of the present invention, it is preferable that the positions of the ridge lines of the folded end parts of the laminated piezoelectric films 12 match each other in the folding-back direction as in the illustrated example. In other words, in the laminated piezoelectric element 10 according to the embodiment of the present invention, it is preferable that the folded ridge lines overlap each other in the planar shape, that is, in a case of being viewed in a plane.

With such a configuration, a region which acts as the laminated piezoelectric element, that is, an effective area in the planar shape with respect to an area of the piezoelectric film 12 can be widened, which is preferable.

In the present invention, as described above, the ridge line of the folded end part is the folding-back line formed at the outer end part of the piezoelectric film 12 by the folding, that is, the line at the outer top of the folded end part.

In the present invention, the fact that the folded ridge line of the piezoelectric film 12 coincides with the folding-back direction includes a case where the position of the ridge line is completely the same as the folding-back direction in the planar shape, and also includes a case where the position of the ridge line is different by +0.1 mm or less in the folding-back direction.

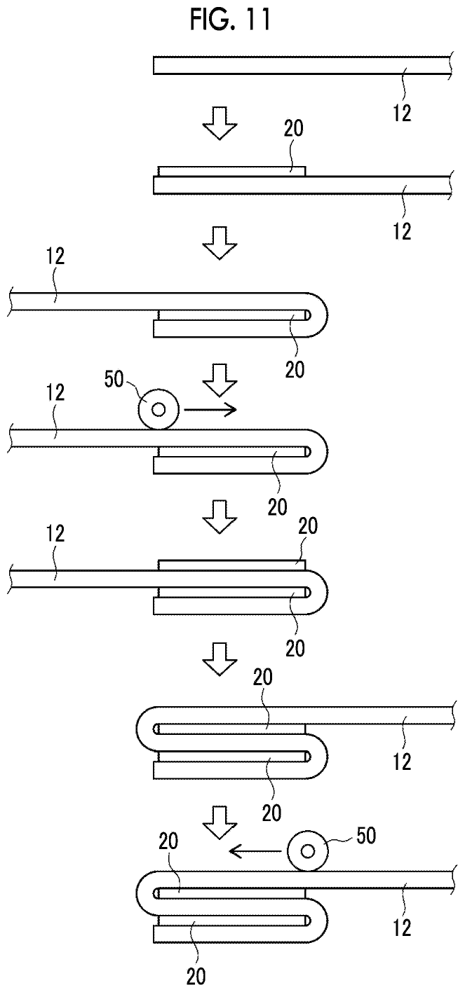

Next, an example of a manufacturing method of the laminated piezoelectric element 10 will be described with reference to FIG. 11 conceptually.

As described above, the laminated piezoelectric element 10 is formed by folding and laminating the piezoelectric film 12, in which the adjacent laminated piezoelectric films 12 are bonded through the bonding layer 20.

As shown in the first and second stages of FIG. 11, the bonding layer 20 is provided on the vicinity of one end part of the piezoelectric film 12, and then the piezoelectric film 12 is folded and laminated as shown in the third stage. The first stage, the second stage, . . . , and the like indicate the number of stages from the top in the drawing.

As shown in the fourth stage, the folded and laminated piezoelectric film 12 is pressed by moving a roller 50 capable of pressing the entire region in a ridge line direction in the folding-back direction, and two layers of the laminated piezoelectric film 12 are bonded to each other. As the roller 50, a roller pair may be used. In addition, a heating roller may be used as the roller 50 to bond the piezoelectric film 12 while heating the piezoelectric film 12, as necessary.

Furthermore, as shown in the fifth stage, the bonding layer 20 is provided on the laminated piezoelectric film 12, and as shown in the sixth stage, the piezoelectric film 12 is folded and laminated. Next, as shown in the seventh stage, the laminated piezoelectric film 12 is bonded by moving the roller 50 capable of pressing the entire region in the ridge line direction in the folding-back direction.

By repeating this operation according to the number of laminated piezoelectric films 12, a laminated piezoelectric element in which a desired number of layers of the piezoelectric film 12 are laminated can be manufactured.

In the manufacturing of the laminated piezoelectric element, it is not necessary to perform the pressing with the roller 50 or the like each time one layer is laminated.

For example, the laminated piezoelectric element may be manufactured by laminating the piezoelectric film in a necessary number of layers and then pressing the entire laminate with a roller or the like.

Here, the laminated piezoelectric element 10 according to the embodiment of the present invention, in which the bonding layer thickness d1 of the bonding layer at the center in the folding-back direction of the piezoelectric film 12 and the film spacing d2 which is a spacing of the piezoelectric films 12 at the folded-back portion in the lamination direction satisfy “d2<d1”, can be manufactured by the following method as an example.

First, a method of using, as the bonding layer 20, a bonding agent which is softened by heating and pressing a produced laminated piezoelectric element 10 in the folding-back direction with a heating roller is exemplified. The bonding agent which is softened by heating may be melted by the heating.

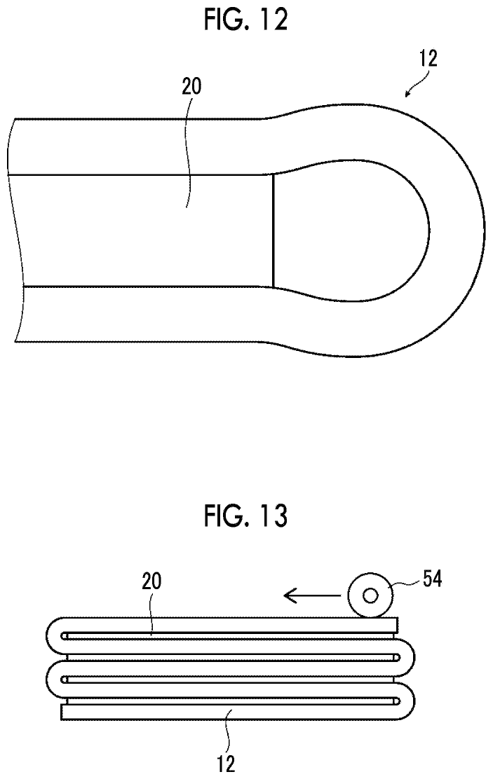

Specifically, in the manufacturing method shown in FIG. 11, the bonding layer 20 is provided on the piezoelectric film 12 such that a void portion is generated on the inner side of the folded end part in the folded-back portion, as conceptually shown in FIG. 12, using a bonding agent which is softened by heating. Specifically, the bonding layer 20 is provided such that the position of the inner end part of the folded-back portion of the piezoelectric film 12 is spaced by a certain distance.

In this manner, in a case where the laminated piezoelectric element is produced as shown in FIG. 11, as conceptually shown in FIG. 13, the entire region of the upper surface of the laminated piezoelectric element (the piezoelectric film 12) is pressed while being heated with a heating roller 54 in the folding-back direction. The pressing may be performed using a heating roller pair.

As described above, the piezoelectric film 12, particularly the piezoelectric film 12 using the polymer-based piezoelectric composite material for the piezoelectric layer 26, has favorable flexibility.

However, such a piezoelectric film 12 also has a certain degree of hardness. Therefore, in the laminated piezoelectric element produced by the method shown in FIG. 11, as shown in FIG. 12, the vicinity of the folded end part in the folded-back portion of the piezoelectric film 12 is slightly bulged by the hardness of the piezoelectric film 12.

Here, in the manufacturing method, as described above, the bonding layer 20 is provided on the piezoelectric film 12 using, as the bonding layer 20, the bonding agent which is softened by heating, and the void is provided at the inner end part of the folded-back portion.

Thereafter, the produced laminated piezoelectric element is pressed in the folding-back direction while the piezoelectric film 12 is heated with the heating roller 54.

In the pressing, in a center portion of the folding-back direction where the bonding layer 20 is completely filled, the bonding layer 20 is not moved even in a case where the bonding layer 20 is softened by heating.

On the other hand, the folded-back portion has a void between the inner end part and the bonding layer 20. Therefore, in a case where the bonding layer 20 is softened by heating with the heating roller 54 and pressing, the bonding layer 20 moves to the void portion by the pressing. Therefore, in the folded-back portion, the thickness of the bonding layer 20 decreases toward the folded end part, and the piezoelectric films 12 are bonded in this state.

As a result, as conceptually shown in FIGS. 8 and 9, in the folded-back portion of the piezoelectric film 12, the laminate of the two piezoelectric films 12 is folded together with the bonding layer 20 in a state in which the thickness gradually decreases in the outer direction.

As a result, the laminated piezoelectric element 10 according to the embodiment of the present invention in which the bonding layer thickness d1 and the film spacing d2 satisfy “d2<d1” can be produced.

In addition, in this manufacturing method, the size of the film spacing d2 can be controlled by the size of the void provided on the inner side of the folded end part, the temperature of the heating roller 54, and the pressing force.

As another method, in the manufacturing method shown in FIG. 11, a method of using two bonding layers 20 by shifting the positions thereof in the folding-back direction is exemplified.

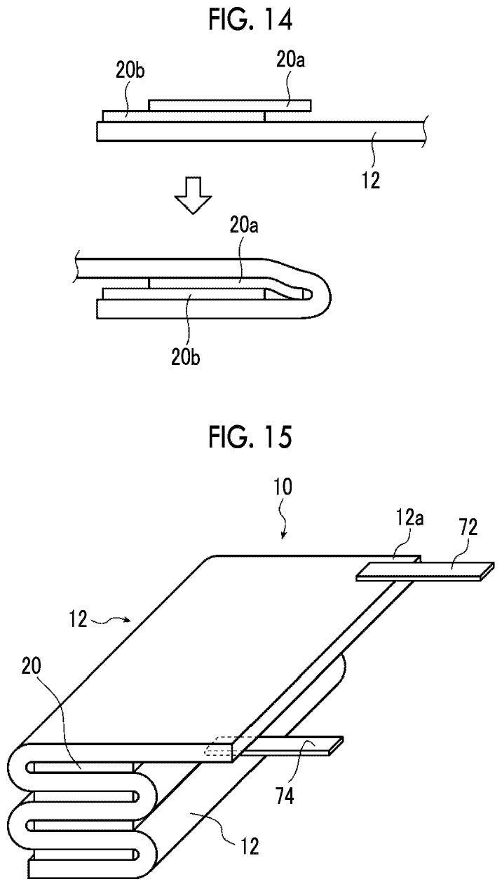

That is, in this method, as conceptually shown in the upper part of FIG. 14, two bonding layers 20 are provided on the piezoelectric film 12 so that the positions thereof are shifted in the folding-back direction. Thereafter, as shown in FIG. 11, the piezoelectric film 12 is folded and laminated, and the piezoelectric film 12 is pressed in the folding-back direction by the roller 50.

By the pressing, as conceptually shown in the lower part of FIG. 14, the folded piezoelectric film 12 is bonded to the one layer of the bonding layer 20 at the folded-back portion, particularly in the vicinity of the folded end part. As a result, the film spacing d2 in the folded-back portion corresponds to a spacing corresponding to one layer of the bonding layer 20.

On the other hand, since the piezoelectric film 12 is bonded to the two bonding layers 20 at the center portion in the folding-back direction, the bonding layer thickness d1 is a thickness of the two bonding layers.

As a result, the laminated piezoelectric element 10 according to the embodiment of the present invention in which the bonding layer thickness d1 and the film spacing d2 satisfy “d2<d1” can be produced. Therefore, in this method, it is not necessary to use layers which are softened by heating as the two bonding layers 20.

In the laminated piezoelectric element 10 according to the embodiment of the present invention, the piezoelectric layer 26 stretches and contracts by applying a driving voltage to the first electrode layer 28 and the second electrode layer 30. For that purpose, it is necessary to electrically connect the first electrode layer 28 and the second electrode layer 30 to an external device such as an external power supply.

As a method of connecting the first electrode layer 28 and the second electrode layer 30 to an external device, various known methods can be used.

As an example, as conceptually shown in FIG. 15, the piezoelectric film 12 is extended at one end part to provide a protruding portion 12a protruding from a region in which the piezoelectric film 12 is laminated. In addition, a method of providing a lead-out wire for electrically connecting the protruding portion 12a to an external device is exemplified.

In the present invention, the protruding portion specifically indicates a region of a single layer which does not overlap with other piezoelectric films 12 in the planar shape, that is, in a case of being viewed from the lamination direction. In addition, in FIG. 15, the thickness of the bonding layer 20 is uniformly shown.

Here, in the laminated piezoelectric element according to the embodiment of the present invention, it is preferable that the piezoelectric film 12 has the protruding portion 12a protruding from the longest side in the planar shape, and a length of the protruding portion in a longitudinal direction of the longest side is 10% or more of the length of the longest side. In the following description, the length of the protruding portion in the longitudinal direction of the longest side in the laminated piezoelectric element is also simply referred to as “length of the protruding portion”.

In the laminated piezoelectric element 10 shown in FIG. 15, since the planar shape is rectangular, it is preferable that the protruding portion 12a protrudes from a long side of the rectangle and has a length of 10% or more of a length of the long side of the rectangle.

In the laminated piezoelectric element according to the embodiment of the present invention, in a case where the protruding portion 12a protrudes from an end part of the laminated piezoelectric element in a lateral direction, it is preferable that a length of the protruding portion 12a in the lateral direction is 50% or more of a length of the laminated piezoelectric element in the lateral direction.

Hereinafter, a case where the planar shape of the laminated piezoelectric element is rectangular will be described as an example, but the following configuration is the same even in a case where the planar shape of the laminated piezoelectric element is not rectangular. In this case, the longest side of the rectangle may be set as the longest side of the planar shape of the corresponding laminated piezoelectric element.

In the present invention, in a case where a length of the long side of the rectangle in the planar shape of the laminated piezoelectric element 10 is denoted as L and a length of the protruding portion is denoted as La, as described above, it is preferable that the length La of the protruding portion 12a is set to be 10% or more of the length L, that is, “La≥L/10”.

Accordingly, the current density in a path through which the driving current flows from the lead wire to the laminated piezoelectric element 10 can be reduced, so that a voltage drop can be reduced and the piezoelectric characteristics can be improved. For example, the above-mentioned electroacoustic transducer can improve the sound pressure.

The length La of the protruding portion 12a is more preferably 50% or more of the length L of the long side in the planar shape of the laminated piezoelectric element 10, still more preferably 70% or more thereof, and particularly preferably 90% or more thereof, and as shown in FIG. 15, it is most preferable that the length La of the protruding portion 12a is the same or longer than the length of the long side in the planar shape of the laminated piezoelectric element 10.

Therefore, in a case of the laminated piezoelectric element 10 in which the ridge line formed by folding the piezoelectric film 12 is along the longitudinal direction as shown in FIG. 1 and FIG. 15, as shown in FIG. 15, it is preferable that one end part in the folding-back direction is extended to form the protruding portion 12a, and a lead-out wire described later is connected to this protruding portion 12a. In this case, the length La of the protruding portion 12a coincides with the length L of the long side of the laminated piezoelectric element. That is, in this case, the protruding portion 12a is the entire region of the long side of the laminated piezoelectric element 10.

As shown in FIG. 15, a first lead-out wire 72 and a second lead-out wire 74 for electrically connecting to an external device such as a power supply device are connected to the protruding portion 12a of the laminated piezoelectric element 10.

The first lead-out wire 72 is a wiring line electrically led out from the first electrode layer 28, and the second lead-out wire 74 is a wiring line electrically led out from the second electrode layer 30. In the following description, in a case where it is unnecessary to distinguish between the first lead-out wire 72 and the second lead-out wire 74, the both lead-out wires are also simply referred to as a lead-out wire.

In the laminated piezoelectric element 10 according to the embodiment of the present invention, a connection method between the electrode layer and the lead-out wire, that is, a lead-out method is not limited, and various methods can be used.

As an example, a method in which a through-hole is formed in the protective layer, an electrode connecting member formed of a metal paste such as a silver paste is provided so as to fill the through-hole, and a lead-out wire is provided in the electrode connecting member is exemplified.

As another method, a method in which a rod-like or sheet-like lead-out electrode is provided between the electrode layer and the piezoelectric layer or between the electrode layer and the protective layer, and the lead-out electrode is connected to a lead-out wire is exemplified. Alternatively, the lead-out wire may be inserted directly between the electrode layer and the piezoelectric layer, or between the electrode layer and the protective layer, and the lead-out wire may be connected to the electrode layer.

As another method, a method in which a part of the protective layer and the electrode layer is projected from the piezoelectric layer in the plane direction, and a lead-out wire is connected to the projected electrode layer is exemplified. The lead-out wire and the electrode layer may be connected by a known method such as a method using a metal paste such as a silver paste, a method using a solder, and a method using a conductive adhesive.

Examples of a suitable method of leading out the electrodes include the method described in JP2014-209724A and the method described in JP2016-015354A.

In addition, in the laminated piezoelectric element 10, instead of extending the end part of the piezoelectric film 12, as shown in FIG. 18 of WO2020/095812A, a protruding portion such as an islet, protruding from the piezoelectric film 12 in the direction of the ridge line, that is, perpendicular to the folding-back direction, may be provided, and a lead-out wire may be provided for connecting an external device to the protruding portion.

Furthermore, in the laminated piezoelectric element according to the embodiment of the present invention, a plurality of these protruding portions may be used in combination as necessary.

The laminated piezoelectric element 10 according to the embodiment of the present invention can be used for various applications as described later. Among these, the laminated piezoelectric element 10 according to the embodiment of the present invention is suitably used as an exciter which outputs a voice by vibrating a vibration plate.

The electroacoustic transducer according to the embodiment of the present invention is obtained by fixing the laminated piezoelectric element 10 according to the embodiment of the present invention to a vibration plate.

FIG. 16 conceptually shows an example in which the electroacoustic transducer according to the embodiment of the present invention is used as a piezoelectric speaker.

The electroacoustic transducer according to the embodiment of the present invention is not limited to the piezoelectric speaker. For example, the electroacoustic transducer according to the embodiment of the present invention can also be used as a microphone which outputs an electrical signal in response to a sound received by the vibration plate, a sensor which converts a vibration of the vibration plate into an electrical signal, and the like.

The piezoelectric speaker according to the embodiment of the present invention is used as an exciter which outputs a voice by bonding the laminated piezoelectric element 10 according to the embodiment of the present invention to a vibration plate and vibrating the vibration plate.

As shown in FIG. 12, a piezoelectric speaker 60 is formed by bonding the laminated piezoelectric element 10 to the vibration plate 62 through a bonding layer 68. In the piezoelectric speaker according to the embodiment of the present invention, the number of laminated piezoelectric elements bonded to one vibration plate 62 is not limited to 1, and a plurality of laminated piezoelectric elements 10 may be bonded to one vibration plate 62. In addition, for example, by providing two laminated piezoelectric elements 10 for one vibration plate 62 and applying different driving voltages to each laminated piezoelectric element 10, for example, a stereo voice may be output with one vibration plate 62.

In the piezoelectric speaker 60 according to the embodiment of the present invention, the vibration plate 62 is not limited, and various sheet-like materials can be used as long as these materials act as a vibration plate which outputs a voice by the vibration of the exciter.

In the piezoelectric speaker 60 according to the embodiment of the present invention, examples of the vibration plate 62 include resin films made of polyethylene terephthalate (PET), polypropylene (PP), polystyrene (PS), polycarbonate (PC), polyphenylene sulfide (PPS), polymethylmethacrylate (PMMA), and polyetherimide (PEI), polyimide (PI), polyethylene naphthalate (PEN), triacetyl cellulose (TAC), cyclic olefin-based resins, or the like; foamed plastic sheets made of foamed polystyrene, foamed styrene, formed polyethylene, or the like; and various kinds of corrugated cardboard materials obtained by bonding other paperboards to one or both surfaces of a corrugated paperboard.

In addition, in the piezoelectric speaker 60 according to the embodiment of the present invention, various display devices such as an organic electro-luminescence (organic light emitting diode (OLED)) display, a liquid crystal display, a micro light emitting diode (LED) display, and an inorganic electroluminescence display can also be suitably used as the vibration plate 62.

Furthermore, in the piezoelectric speaker 60 according to the embodiment of the present invention, electronic devices such as a smartphone, a mobile phone, a tablet terminal, a personal computer such as a laptop computer, and a wearable device such as a smart watch, can also be suitably used as the vibration plate 62.

Moreover, in the piezoelectric speaker according to the embodiment of the present invention, thin film metals consisting of various metals such as stainless steel, aluminum, copper, and nickel, and various alloys can also be suitably used as the vibration plate 62.

In addition, in a case where the vibration plate 62 is a display device, an electronic device, or the like, the vibration plate 62 may be flexible.

As described above, the piezoelectric film 12 has favorable flexibility. Therefore, the laminated piezoelectric element 10 according to the embodiment of the present invention, which is obtained by laminating the piezoelectric film 12, also has favorable flexibility. Accordingly, a piezoelectric speaker which can be curved, bent, folded, rolled, or the like can be realized by using the vibration plate 62 having flexibility.

In the piezoelectric speaker 60 according to the embodiment of the present invention, the bonding layer 68 that bonds the vibration plate 62 to the laminated piezoelectric element 10 is not limited, and various bonding agents can be used as long as the vibration plate 62 and the laminated piezoelectric element 10 (piezoelectric film 12) can be bonded to each other.

In the piezoelectric speaker 60 according to the embodiment of the present invention, as the bonding layer 68 for bonding the vibration plate 62 and the laminated piezoelectric element 10 to each other, various agents as in the bonding layer 20 for bonding the adjacent piezoelectric films 12 described above can be used. In addition, the same applies to the preferred bonding layer 68.

In the piezoelectric speaker 60 according to the embodiment of the present invention, a thickness of the bonding layer 68 is not limited, and a thickness capable of exhibiting sufficient bonding strength may be appropriately set depending on the forming material of the bonding layer 68.

Here, in the piezoelectric speaker 60 according to the embodiment of the present invention, as the bonding layer 68 is thinner, the effect of transmitting the stretching and contracting energy (vibration energy) of the laminated piezoelectric element 10, that is, the piezoelectric film 12 is higher, and the energy efficiency is higher. In addition, in a case where the bonding layer is thick and has high rigidity, there is a possibility that the stretch and contraction of the laminated piezoelectric element 10 may be constrained.

In consideration of this point, the thickness of the bonding layer 68 for bonding the vibration plate 62 and the laminated piezoelectric element 10 is preferably 10 to 1,000 μm, more preferably 30 to 500 μm, and still more preferably 50 to 300 μm in terms of the thickness after bonding.

As described above, in the laminated piezoelectric element 10 according to the embodiment of the present invention, the piezoelectric film 12 is formed by sandwiching the piezoelectric layer 26 between the first electrode layer 28 and the second electrode layer 30.

In the piezoelectric layer 26, it is preferable that the piezoelectric particles 40 are dispersed in the polymer matrix 38.

In a case where a voltage is applied to the second electrode layer 30 and the first electrode layer 28 of the piezoelectric film 12 including such a piezoelectric layer 26, the piezoelectric particles 40 stretch and contract in the polarization direction according to the applied voltage. As a result, the piezoelectric film 12 (piezoelectric layer 26) contracts in the thickness direction. At the same time, the piezoelectric film 12 stretches and contracts in the plane direction due to the Poisson's ratio.

A degree of stretch and contraction is approximately 0.01% to 0.1%.

As described above, the thickness of the piezoelectric layer 26 is preferably approximately 8 to 300 μm. Accordingly, the degree of stretch and contraction in the thickness direction is as extremely small as approximately 0.3 μm at the maximum.

On the contrary, the piezoelectric film 12, that is, the piezoelectric layer 26, has a size much larger than the thickness in a plane direction. Therefore, for example, in a case where a length of the piezoelectric film 12 is 20 cm, the piezoelectric film 12 stretches and contracts by a maximum of approximately 0.2 mm by the application of the voltage.

As described above, the laminated piezoelectric element 10 is formed by laminating the piezoelectric film 12 in five layers by folding the piezoelectric film 12. In addition, the laminated piezoelectric element 10 is bonded to the vibration plate 62 through the bonding layer 68.

The laminated piezoelectric element 10 also stretches and contracts in the same direction by the stretch and contraction of the piezoelectric film 12. The stretch and contraction of the laminated piezoelectric element 10 causes the vibration plate 62 to bend, and as a result, the vibration plate 62 vibrates in the thickness direction.

The vibration plate 62 generates a sound using the vibration in the thickness direction. That is, the vibration plate 62 vibrates according to the magnitude of the voltage (driving voltage) applied to the piezoelectric film 12, and generates a sound according to the driving voltage applied to the piezoelectric film 12.

Here, it has been known that, in a case where a general piezoelectric film consisting of a polymer material such as PVDF is stretched in a uniaxial direction after being subjected to the polarization treatment, molecular chains are aligned with respect to the stretching direction, and as a result, high piezoelectric characteristics are obtained in the stretching direction. Therefore, a typical piezoelectric film has in-plane anisotropy as a piezoelectric characteristic and has anisotropy in the amount of stretch and contraction in the plane direction in a case where a voltage is applied.

On the other hand, in the laminated piezoelectric element 10, since the piezoelectric film 12 consisting of a polymer-based piezoelectric composite material in which the piezoelectric particles 40 are dispersed in the polymer matrix 38 as shown in FIG. 4 has large piezoelectric characteristics without stretching treatment after the polarization treatment, the piezoelectric film 12 has no in-plane anisotropy as a piezoelectric characteristic, and stretches and contracts isotropically in all directions in the plane direction. That is, in the laminated piezoelectric element 10 of the illustrated example, the piezoelectric film 12 shown in FIG. 4, constituting the laminated piezoelectric element 10, stretches and contracts isotropically and two-dimensionally. According to the laminated piezoelectric element 10 in which such piezoelectric films 12 that stretch and contract isotropically and two-dimensionally are laminated, compared to a case where typical piezoelectric films formed of PVDF or the like that stretch and contract greatly in only one direction are laminated, the vibration plate 62 can be vibrated with a large force, and a louder and more beautiful sound can be generated.

As described above, the laminated piezoelectric element 10 of the illustrated example has five layers of such a piezoelectric film 12 laminated. In the laminated piezoelectric element 10 of the illustrated example, the adjacent piezoelectric films 12 are bonded to each other through the bonding layer 20.

Therefore, even in a case where the rigidity of each piezoelectric film 12 is low and the stretching and contracting force thereof is small, the rigidity is increased by laminating the piezoelectric films 12, and the stretching and contracting force as the laminated piezoelectric element 10 is increased. As a result, in the laminated piezoelectric element 10, even in a case where the vibration plate 62 has a certain degree of rigidity, the vibration plate 62 is sufficiently bent with a large force, and the vibration plate 62 can be sufficiently vibrated in the thickness direction, so that the vibration plate 62 can generate the sound.

In addition, in a case where the thickness of the piezoelectric layer 26 increases, the stretching and contracting force of the piezoelectric film 12 is increased, but the driving voltage required for stretching and contracting the film is increased by the same amount. Here, as described above, in the laminated piezoelectric element 10, since the maximum thickness of the piezoelectric layer 26 is preferably approximately 300 μm, the piezoelectric film 12 can be sufficiently stretched and contracted even in a case where the voltage applied to each piezoelectric film 12 is small.

In addition to the above-described piezoelectric speaker (electroacoustic transducer), such a laminated piezoelectric element according to the embodiment of the present invention suitably used for various applications, such as various sensors, acoustic devices, haptics, ultrasonic transducers, actuators, damping materials (dampers), and vibration power generators.

Specifically, examples of the sensor including the laminated piezoelectric element according to the embodiment of the present invention include sound wave sensors, ultrasound wave sensors, pressure sensors, tactile sensors, strain sensors, and vibration sensors. The sensor including the piezoelectric film and the laminated piezoelectric element according to the embodiment of the present invention are particularly useful for infrastructure inspection such as crack detection and examination at a manufacturing site such as foreign matter contamination detection.

Examples of the acoustic device including the laminated piezoelectric element according to the embodiment of the present invention include microphones, pickups, and known speakers and exciters, in addition to the above-described piezoelectric speaker (exciter). Examples of specific applications of the acoustic device including the laminated piezoelectric element according to the embodiment of the present invention include noise cancellers used for cars, trains, airplanes, robots, and the like, artificial voice bands, buzzers to prevent pests and beasts from invading, furniture having a voice output function, wallpaper, photos, helmets, goggles, headrests, signage, and robots.

Application examples of the haptic including the laminated piezoelectric element according to the embodiment of the present invention include automobiles, smartphones, smart watches, and game machines.

Examples of the ultrasonic transducer including the laminated piezoelectric element according to the embodiment of the present invention include ultrasound probes and hydrophones.

Examples of the applications of the actuator including the laminated piezoelectric element according to the embodiment of the present invention include prevention of attachment of water droplets, transport, stirring, dispersion, and polishing.

Application examples of the damping material including the laminated piezoelectric element according to the embodiment of the present invention include containers, vehicles, buildings, and sports equipment such as skis and rackets.

Furthermore, application examples of the vibration power generator including the laminated piezoelectric element according to the embodiment of the present invention include roads, floors, mattresses, chairs, shoes, tires, wheels, and computer keyboards.

Hereinbefore, the laminated piezoelectric element and electroacoustic transducer according to the embodiment of the present invention have been described in detail, but the present invention is not limited to the above-described examples, and various improvements or modifications may be made within a range not departing from the scope of the present invention.

### EXAMPLES

Hereinafter, the present invention will be described in more detail with reference to specific examples of the present invention.

### [Production of Piezoelectric Film]

A piezoelectric film shown in FIG. 4 was produced by the methods shown in FIGS. 5 to 7.

First, cyanoethylated PVA (CR-V, manufactured by Shin-Etsu Chemical Co., Ltd.) was dissolved in dimethylformamide (DMF) at the following compositional ratio. Thereafter, PZT particles as piezoelectric particles were added to the solution at the following compositional ratio, and the solution was stirred using a propeller mixer (rotation speed: 2000 rpm), thereby preparing a coating material for forming a piezoelectric layer.

| | |
|---|---|
| PZT Particles: | 300 parts by mass |
| Cyanoethylated PVA: | 30 parts by mass |
| DMF: | 70 parts by mass |

PZT particles which were obtained by sintering mixed powder, formed by wet-mixing powder of a Pb oxide, a Zr oxide, and a Ti oxide as main components using a ball mill such that the amount of Zr and the amount of Ti respectively reached 0.52 moles and 0.48 moles with respect to 1 mole of Pb, at 800° C. for 5 hours and being subjected to a crushing treatment were used as the PZT particles.

On the other hand, two sheets of sheet-like materials obtained by performing vacuum vapor deposition on a copper thin film having a thickness of 300 nm were prepared on a PET film having a thickness of 4 μm. That is, in the present example, the first electrode layer and the second electrode layer were copper-deposited thin films having a thickness of 300 nm, and the first protective layer and the second protective layer were PET films having a thickness of 4 μm.

The copper thin film (second electrode layer) of one sheet-like material was coated with the coating material for forming a piezoelectric layer, which was prepared in advance, using a slide coater.

Next, the material obtained by coating the sheet-like material with the coating material was heated and dried on a hot plate at 120° C. to evaporate DMF. In this manner, a laminate in which the second electrode layer made of copper was provided on the second protective layer made of PET and the piezoelectric layer (polymer-based piezoelectric composite material layer) having a thickness of 50 μm was formed thereon was produced.

The produced piezoelectric layer (laminate) was subjected to a calender treatment using a heating roller pair. A temperature of the heating roller pair was set to 100° C.

After performing the calender treatment, the produced piezoelectric layer was subjected to a polarization treatment in a thickness direction.

The other sheet-like material was laminated on the laminate facing the copper thin film (first electrode layer) toward the piezoelectric layer.

Next, the laminate of the laminate and the sheet-like material was subjected to thermal compression bonding at a temperature of 120° C. using a heating roller pair to adhere the piezoelectric layer and the first electrode layer, thereby producing a piezoelectric film as shown in FIG. 4.

### Example 1

The produced piezoelectric film was cut into a rectangle having a size of 20×15 cm.

As shown in FIG. 11, the piezoelectric film was provided with a bonding layer, and then folded and pressed with a roller to be bonded to each other, and this operation was repeated at intervals of 3 cm in a direction of 15 cm. As a result, as shown in FIG. 2, a laminated piezoelectric element having a planar shape of 20×3 cm, which was obtained by laminating the piezoelectric film in five layers and bonding the adjacent laminated piezoelectric films with a bonding layer, was produced. Therefore, in the laminated piezoelectric element, the side having a length of 20 cm is a ridge line (folding-back line).

As the bonding layer, CRANBERRY G5 (thickness: 30 μm) manufactured by KURABO INDUSTRIES LTD. was used. The bonding layer was softened by heating. In addition, the bonding layer was provided at a position spaced from a folded end part, such that a void was formed at the folded end part on an inner side of a folded-back portion of the piezoelectric film.

A roller having a length of 220 mm was used, and the piezoelectric film was pressed and bonded while being moved in the folding-back direction and heating a seat on which the piezoelectric film was fixed to 100° C.

After producing a laminated piezoelectric element in which the piezoelectric film was laminated in five layers, the laminated piezoelectric element was produced by pressing the entire upper surface thereof with a heating roller as shown in FIG. 13. A moving direction of the heating roller was set as the folding-back direction of the piezoelectric film.

The pressing of the laminated piezoelectric element with the heating roller was performed using a laminator (manufactured by Taisei Laminator Co., LTD., VH570FG). The temperature of the heating roller was 120° ° C., and the roller set pressure was 0.6 MP. The pressing of the laminated piezoelectric element was performed four times.

### Comparative Example 1

A laminated piezoelectric element was produced in the same manner as in Example 1, except that the piezoelectric film was laminated in five layers and the pressing with a heating roller was not performed.

### Comparative Example 2

A laminated piezoelectric element was produced in the same manner as in Comparative Example 1, except that a folding width of the piezoelectric film was widened by 0.1 mm.

### [Production of Piezoelectric Speaker]

As a vibration plate, a PET film having a thickness of 50 μm was prepared.

The PET film was placed on a stainless steel workbench. Next, a double-sided tape (MUTAK double-sided tape, manufactured by YS GRAPHICS) having a thickness of 80 μm was laminated on the PET film as a bonding layer.

The produced laminated piezoelectric element was placed on the bonding layer. Thereafter, using a roller having a roller diameter of 40 mm, a rubber thickness of 10 mm, a roller width of 40 mm, and a hardness of 40 degrees, the laminated piezoelectric element was pressed against the PET film to bond the laminated piezoelectric element to the vibration plate, thereby producing a piezoelectric speaker as shown in FIG. 16. The roller load was 5 kg. In addition, the pressing with a roller was performed 10 times.

### EVALUATION

### <Detection of Broken Portion of Electrode Layer>

The entire region of folded ridge lines of the piezoelectric film in the laminated piezoelectric element was observed with a microscope (manufactured by KEYENCE CORPORATION, VHX-200) to detect the presence or absence of a broken portion in the electrode layer.

A case where no broken portion was confirmed was evaluated as A, and a case where the broken portion was confirmed was evaluated as B.

The results are shown in the table.

[Measurement of Bonding Layer Thickness d1 and Film Spacing d2]

Regarding the laminated piezoelectric element constituting the piezoelectric speaker, as shown in FIG. 10, a center measurement line x1 and measurement lines x2 to x5 were set. Furthermore, the laminated piezoelectric element was cut along each measurement line, and the cross section was observed with an SEM.

From the SEM image, the bonding layer thickness d1, which was a thickness of the bonding layer at the center portion of each cross section in the folding-back direction, was measured. In addition, from the SEM image, as shown in FIGS. 8 and 9, the film spacing d2, which was a spacing between the piezoelectric films at the folded-back portion of the piezoelectric film in each cross section in the lamination direction, was measured.

The average of the bonding layer thicknesses d1 and the average of the film spacings d2 in the five cross sections were calculated, and the bonding layer thickness d1 and the film spacing d2 in the laminated piezoelectric element were obtained.

Such measurements of the bonding layer thickness d1 and the film spacing d2 were performed for all of the four bonding layers.

Furthermore, as described above, the average of the bonding layer thicknesses d1 and the average of the film spacings d2 at one folded-back portion in the folding-back direction and the average of the bonding layer thicknesses d1 and the average of the film spacings d2 at the other folded-back portion in the folding-back direction were calculated. As described above, one folded-back portion and the other folded-back portion in the folding-back direction were, for example, the right and left folded-back portions in FIG. 1.

In any of the laminated piezoelectric elements, the average of the bonding layer thicknesses d1 and the average of the film spacings d2 were the same in the one folded-back portion and the other folded-back portion in the folding-back direction.

The results are also shown in the table below.

TABLE 1

| | Laminated piezoelectric element | | | | Bonding | | |
|---|---|---|---|---|---|---|---|
| | | | Length | | layer | Film | Evaluation |
| | Thickness of | Thickness | of | Number | thickness | spacing | Detection |
| | piezoelectric | of electrode | folding | of | d1 | d2 | of broken |
| | layer [μm] | layer [nm] | [mm] | lamination | [μm] | [μm] | portion |
| Example 1 | 50 | 300 | 30 | 5 | 30 | 20 | A |
| Comparative | | | | | 30 | 50 | B |
| Example 1 | | | | | | | |
| Comparative | | | | | 30 | 100 | B |
| Example 2 | | | | | | | |

The length of folding refers to a length of the piezoelectric in the folding-back direction.

As shown in the table, in the laminated piezoelectric element according to the embodiment of the present invention, in which the piezoelectric films were folded and laminated and the adjacent piezoelectric films were bonded to each other with the bonding layer, the bonding layer thickness d1 and the film spacing d2 satisfied “d2<d1”, and the broken portion of the electrode layer was not found in the folded-back portion of the piezoelectric film. Therefore, in the piezoelectric speaker according to the embodiment of the present invention, in which the laminated piezoelectric element according to the embodiment of the present invention was used as an exciter, it was possible to appropriately output a voice at a target sound pressure.

On the other hand, in the laminated piezoelectric elements of Comparative Examples, in which the bonding layer thickness d1 and the film spacing d2 did not satisfy “d2<d1”, it was considered that the broken portion of the electrode layer was generated in the folded-back portion of the piezoelectric film by the pressing in a case of bonding the vibration plate (PET film). Therefore, there was a possibility that the piezoelectric speaker using the laminated piezoelectric element as an exciter could not output a voice at a target sound pressure.

From the above results, the effect of the present invention is clear.

The present invention can be suitably used for a piezoelectric speaker in various applications.

### EXPLANATION OF REFERENCES

10: laminated piezoelectric element
12: piezoelectric film
20, 68: bonding layer
26: piezoelectric layer
28: first electrode layer
30: second electrode layer
32: first protective layer
34: second protective layer
38: polymer matrix
40: piezoelectric particle
42a, 42b: sheet-like material
46: laminate
50: roller
54: heating roller
60: piezoelectric speaker
62: vibration plate
72: first lead-out wire
74: second lead-out wire
S: center portion

What is claimed is:

1. A laminated piezoelectric element obtained by folding a piezoelectric film having flexibility to laminate the piezoelectric film into a plurality of layers, the laminated piezoelectric element comprising:
a bonding layer for bonding adjacent layers to each other in the lamination of the piezoelectric film,
wherein, in a case where a thickness of the bonding layer at a center portion in a folding-back direction of the piezoelectric film is denoted as d1 and a spacing between piezoelectric films at a folded-back portion of the piezoelectric film in a lamination direction of the piezoelectric film is denoted as d2, a relationship of “d2<d1” is satisfied.

2. The laminated piezoelectric element according to claim 1,
wherein a position of an outer end portion of the folded-back portion of the piezoelectric film matches in the folding-back direction of the piezoelectric film.

3. The laminated piezoelectric element according to claim 1,
wherein the piezoelectric film is polarized in a thickness direction.

4. The laminated piezoelectric element according to claim 1,
wherein the piezoelectric film includes a piezoelectric layer, electrode layers provided on both surfaces of the piezoelectric layer, and protective layers provided to cover the electrode layers.

5. The laminated piezoelectric element according to claim 4,
wherein the piezoelectric layer is a polymer-based piezoelectric composite material having piezoelectric particles in a polymer material.

6. The laminated piezoelectric element according to claim 5,
wherein the polymer material has a cyanoethyl group.

7. The laminated piezoelectric element according to claim 6,
wherein the polymer material is cyanoethylated polyvinyl alcohol.

8. The laminated piezoelectric element according to claim 1,
wherein the piezoelectric film has a rectangular shape in a case of being viewed in the lamination direction of the piezoelectric film.

9. The laminated piezoelectric element according to claim 1,
wherein the piezoelectric film has a protruding portion where the piezoelectric film protrudes from a longest side which is a longest side in a case of being viewed in the lamination direction of the piezoelectric film, and
a length of the protruding portion in a longitudinal direction of the longest side is 10% or more of an entire length of the longest side.

10. An electroacoustic transducer comprising:
the laminated piezoelectric element according to claim 1; and
a vibration plate to which the laminated piezoelectric element is fixed.

11. The electroacoustic transducer according to claim 10,
wherein the vibration plate has flexibility.

12. The laminated piezoelectric element according to claim 2,
wherein the piezoelectric film is polarized in a thickness direction.

13. The laminated piezoelectric element according to claim 2,
wherein the piezoelectric film includes a piezoelectric layer, electrode layers provided on both surfaces of the piezoelectric layer, and protective layers provided to cover the electrode layers.

14. The laminated piezoelectric element according to claim 13,
wherein the piezoelectric layer is a polymer-based piezoelectric composite material having piezoelectric particles in a polymer material.

15. The laminated piezoelectric element according to claim 14,
wherein the polymer material has a cyanoethyl group.

16. The laminated piezoelectric element according to claim 15,
wherein the polymer material is cyanoethylated polyvinyl alcohol.

17. The laminated piezoelectric element according to claim 2,
wherein the piezoelectric film has a rectangular shape in a case of being viewed in the lamination direction of the piezoelectric film.

18. The laminated piezoelectric element according to claim 2,
wherein the piezoelectric film has a protruding portion where the piezoelectric film protrudes from a longest side which is a longest side in a case of being viewed in the lamination direction of the piezoelectric film, and
a length of the protruding portion in a longitudinal direction of the longest side is 10% or more of an entire length of the longest side.

19. An electroacoustic transducer comprising:
the laminated piezoelectric element according to claim 2; and
a vibration plate to which the laminated piezoelectric element is fixed.

20. The electroacoustic transducer according to claim 19,
wherein the vibration plate has flexibility.
